(19) United States
(12) Patent Application Publication
(10) Pub. No.: US 2026/0107827 A1
(43) Pub. Date: Apr. 16, 2026

(54) SIDEWALL PADDING FOR A SEMICONDUCTOR DIE FOR STRESS ABSORPTION AND METHODS OF FORMING THE SAME

(71) Applicant: Taiwan Semiconductor Manufacturing Company Limited, Hsinchu (TW)

(72) Inventors: Chieh-Lung LAI, Taichung City (TW); Meng-Liang LIN, Hsinchu (TW); Hsien-Wei CHEN, Hsinchu City (TW); Kathy YAN, Hsinchu (TW)

(21) Appl. No.: 18/915,075

(22) Filed: Oct. 14, 2024

(51) Int. Cl. H01L 23/31; H01L 21/56; H01L 21/78; H01L 23/00; H01L 23/29; H01L 25/065

(52) U.S. Cl. CPC H10W 74/134; H10P 54/00; H10W 74/014; H10W 74/141; H10W 74/15; H10W 74/43; H10W 74/47; H10W 90/00; H10W 90/724; H10W 90/734

(57) ABSTRACT

A substrate including a two-dimensional array of semiconductor dies and a rectangular grid of trenches that laterally extend along dicing channel regions may be provided. The rectangular grid of trenches may be filled with an elastic dielectric fill material. A combination of the two-dimensional array of semiconductor dies and a grid-shaped portion of the elastic dielectric fill material filling the rectangular grid of trenches may be diced along the dicing channel regions. A plurality of elastically padded semiconductor dies is formed. Each of the elastically padded semiconductor dies includes a respective singulated semiconductor die that includes semiconductor devices and metal bump structures located on dielectric material layers, and further includes an elastic protective material portion including a portion of the elastic dielectric fill material and laterally surrounding the dielectric material layers.

### BACKGROUND

An underfill material around a semiconductor die may delaminate or develop cracks under mechanical stress that in turn may be applied to the semiconductor die. Such structural damages to the underfill material degrade reliability of semiconductor packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a first exemplary structure including a device wafer that contains a two-dimensional array of semiconductor dies according to a first embodiment of the present disclosure. FIG. 1B is a top-down view of the first exemplary structure of FIG. 1A. The vertical plane A-A′ is the cut plane of the vertical cross-sectional view of FIG. 1A.

FIG. 1C is a top-down view of an alternative embodiment of the first exemplary structure.

FIG. 2A is a vertical cross-sectional view of the first exemplary structure after formation of a rectangular grid of trenches in the device wafer according to the first embodiment of the present disclosure. FIG. 2B is a top-down view of the first exemplary structure of FIG. 2A. The vertical plane A-A′ is the cut plane of the vertical cross-sectional view of FIG. 2A.

FIG. 2C is a vertical cross-sectional view of the first exemplary structure along the vertical plane C-C′ of FIG. 2B.

FIG. 2D is a vertical cross-sectional view of the a first alternative embodiment of the first exemplary structure at a processing step that corresponds to the processing steps of FIGS. 2A-2C.

FIG. 2E is a vertical cross-sectional view of a second alternative embodiment of the first exemplary structure after formation of a set of trenches in the device wafer according to the first embodiment of the present disclosure.

FIG. 2F is a top-down view of the first exemplary structure of FIG. 2E. The vertical plane E-E′ is the cut plane of the vertical cross-sectional view of FIG. 2E.

FIG. 2G is a vertical cross-sectional view of the first exemplary structure along the vertical plane G-G′ of FIG. 2F.

FIG. 3A is a vertical cross-sectional view of the first exemplary structure after formation of an elastic dielectric fill material layer according to the first embodiment of the present disclosure. FIG. 3B is a top-down view of the first exemplary structure of FIG. 3A. The vertical plane A-A′ is the cut plane of the vertical cross-sectional view of FIG. 3A.

FIG. 3C is a vertical cross-sectional view of the first exemplary structure along the vertical plane C-C′ of FIG. 3B.

FIG. 3D is a vertical cross-sectional view of the a first alternative embodiment of the first exemplary structure at a processing step that corresponds to the processing steps of FIGS. 3A-3C.

FIG. 3E is a vertical cross-sectional view of a second alternative embodiment of the first exemplary structure after formation of an elastic dielectric fill material layer according to the first embodiment of the present disclosure.

FIG. 3F is a top-down view of the first exemplary structure of FIG. 3E. The vertical plane E-E′ is the cut plane of the vertical cross-sectional view of FIG. 3E.

FIG. 3G is a vertical cross-sectional view of the first exemplary structure along the vertical plane G-G′ of FIG. 3F.

FIG. 4A is a vertical cross-sectional view of the first exemplary structure after formation of an elastic dielectric fill material grid and thinning of the semiconductor wafer according to the first embodiment of the present disclosure.

FIG. 4B is a top-down view of the first exemplary structure of FIG. 4A. The vertical plane A-A′ is the cut plane of the vertical cross-sectional view of FIG. 4A.

FIG. 4C is a vertical cross-sectional view of the first exemplary structure along the vertical plane C-C′ of FIG. 4B.

FIG. 4D is a vertical cross-sectional view of the a first alternative embodiment of the first exemplary structure at a processing step that corresponds to the processing steps of FIGS. 4A-4C.

FIG. 4E is a vertical cross-sectional view of a second alternative embodiment of the first exemplary structure after formation of an elastic dielectric fill material grid and thinning of the semiconductor wafer according to the first embodiment of the present disclosure.

FIG. 4F is a top-down view of the first exemplary structure of FIG. 4E. The vertical plane E-E′ is the cut plane of the vertical cross-sectional view of FIG. 4E.

FIG. 4G is a vertical cross-sectional view of the first exemplary structure along the vertical plane G-G′ of FIG. 4F.

FIG. 5A is a vertical cross-sectional view of the first exemplary structure after dicing a combination of the two-dimensional array of semiconductor dies and the elastic dielectric fill material grid into a plurality of elastically padded semiconductor dies according to the first embodiment of the present disclosure.

FIG. 5B is a top-down view of the first exemplary structure of FIG. 5A. The vertical plane A-A′ is the cut plane of the vertical cross-sectional view of FIG. 5A.

FIG. 5C is a vertical cross-sectional view of the first exemplary structure along the vertical plane C-C′ of FIG. 5B. FIG. 5D is a top-down view of a diced semiconductor die within the first exemplary structure of FIGS. 5A-5C.

FIG. 5E is a vertical cross-sectional view of the a first alternative embodiment of the first exemplary structure at a processing step that corresponds to the processing steps of FIGS. 5A-5C.

FIG. 5F is a vertical cross-sectional view of a second alternative embodiment of the first exemplary structure after dicing a combination of the two-dimensional array of semiconductor dies and the elastic dielectric fill material grid into a plurality of elastically padded semiconductor dies according to the first embodiment of the present disclosure.

FIG. 5G is a top-down view of the first exemplary structure of FIG. 5F. The vertical plane F-F′ is the cut plane of the vertical cross-sectional view of FIG. 5F.

FIG. 5H is a vertical cross-sectional view of the first exemplary structure along the vertical plane H-H′ of FIG. 5G.

FIG. 5I is a top-down view of an elastically padded semiconductor die.

FIG. 6A is a vertical cross-sectional view of a portion of a two-dimensional array of interposers formed over a first carrier wafer according to an embodiment of the present disclosure.

FIG. 6B is a top-down view of the portion of the wafer of FIG. 6A.

FIG. 7A is a vertical cross-sectional view of the portion of the two-dimensional array of interposers after formation of interposer-side bonding structures according to an embodiment of the present disclosure.

FIG. 7B is a top-down view of the portion of the wafer of FIG. 7A.

FIG. 8A is a vertical cross-sectional view of a portion of a bonded assembly including a two-dimensional array of interposers and elastically padded semiconductor dies according to an embodiment of the present disclosure.

FIG. 8B is a top-down view of the portion of the bonded assembly of FIG. 8A.

FIG. 9A is a vertical cross-sectional view of a portion of the bonded assembly including the two-dimensional array of interposers and the elastically padded semiconductor dies after formation of underfill material portions according to an embodiment of the present disclosure.

FIG. 9B is a magnified vertical cross-sectional view of a bonded assembly of FIG. 9A.

FIG. 9C is a vertical cross-sectional view of an alternative configuration of a portion of the bonded assembly including the two-dimensional array of interposers and the elastically padded semiconductor dies after formation of underfill material portions according to an embodiment of the present disclosure.

FIG. 10A is a vertical cross-sectional view of a portion of a reconstituted wafer after formation of a molding compound matrix according to an embodiment of the present disclosure.

FIG. 10B is a top-down view of the portion of the reconstituted wafer of FIG. 10A.

FIG. 11 is a vertical cross-sectional view of the reconstituted wafer after attaching a second carrier wafer and detaching the first carrier wafer according to an embodiment of the present disclosure.

FIG. 12 is a vertical cross-sectional view of a portion of the reconstituted wafer after formation of interposer bonding pads according to an embodiment of the present disclosure.

FIG. 13 is a vertical cross-sectional view of a portion of the reconstituted wafer after detaching the second carrier wafer according to an embodiment of the present disclosure.

FIG. 14 is a vertical cross-sectional view of a region of the reconstituted wafer during dicing according to an embodiment of the present disclosure.

FIG. 15A is a vertical cross-sectional view of a fan-out package according to the first embodiment of the present disclosure.

FIG. 15B is a horizontal cross-sectional view of the fan-out package along the horizontal plane B-B′ of FIG. 10A.

FIG. 16A is a vertical cross-sectional view of a packaging substrate according to an embodiment of the present disclosure.

FIG. 16B is a top-down view of the packaging substrate of FIG. 16A.

FIG. 17 is a vertical cross-sectional view of a bonded assembly after attaching the fan-out package to the packaging substrate according to the first embodiment of the present disclosure.

FIG. 18 is a vertical cross-sectional view of the bonded assembly after attaching the packaging substrate to a printed circuit board according to an embodiment of the present disclosure.

FIG. 19A is a vertical cross-sectional view of a second exemplary structure that includes a two-dimensional array of semiconductor dies disposed on a carrier substrate according to a second embodiment of the present disclosure.

FIG. 19B is a top-down view of the second exemplary structure of FIG. 19A. The vertical plane A-A′ is the cut plane of the vertical cross-sectional view of FIG. 19A.

FIG. 20A is a vertical cross-sectional view of the second exemplary structure after formation of an elastic dielectric fill material layer according to the second embodiment of the present disclosure.

FIG. 20B is a top-down view of the second exemplary structure of FIG. 20A. The vertical plane A-A′ is the cut plane of the vertical cross-sectional view of FIG. 20A.

FIG. 21A is a vertical cross-sectional view of the second exemplary structure after formation of an elastic dielectric fill material grid according to the second embodiment of the present disclosure.

FIG. 21B is a top-down view of the second exemplary structure of FIG. 21A. The vertical plane A-A′ is the cut plane of the vertical cross-sectional view of FIG. 21A.

FIG. 22A is a vertical cross-sectional view of the second exemplary structure after detaching the carrier substrate and dicing a combination of the two-dimensional array of semiconductor dies and the elastic dielectric fill material grid into a plurality of elastically padded semiconductor dies according to the second embodiment of the present disclosure.

FIG. 22B is a top-down view of the second exemplary structure of FIG. 22A. The vertical plane A-A′ is the cut plane of the vertical cross-sectional view of FIG. 22A.

FIG. 22C is a top-down view of an elastically padded semiconductor die.

FIG. 23 is a vertical cross-sectional view of a portion of a reconstituted wafer after formation of a molding compound matrix according to an embodiment of the present disclosure.

FIG. 24 is a vertical cross-sectional view of a bonded assembly after attaching a packaging substrate to a printed circuit board according to an embodiment of the present disclosure.

FIG. 25 is a first flowchart illustrating steps for forming a device structure according to an embodiment of the present disclosure.

FIG. 26 is a second flowchart illustrating steps for forming a device structure according to an embodiment of the present disclosure.

### DETAILED DESCRIPTION

The following disclosure provides many different embodiments, or examples, for implementing various features of the provided subject matter. Specific examples of components and arrangements are described below to simplify the present disclosure. These are merely examples, and are not intended to be limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The present disclosure relates to a method for manufacturing semiconductor devices that effectively addresses the common issues of cracks and delamination during the dicing and packaging processes. Related methods often fail to provide adequate protection around the edges of semiconductor dies, leading to compromised reliability and performance. Embodiments of the present disclosure use an elastic dielectric fill material to provide a protective frame around each die for absorbing external mechanical stress, thereby enhancing mechanical stability and device integrity.

A two-dimensional array of semiconductor dies and a rectangular grid of trenches thereamongst are provided. The trenches, which are wider than the dicing channels, may be filled with an elastic dielectric material, which acts as a buffer to absorb mechanical stress. The trenches are designed with a uniform depth that exceeds the total thickness of the dielectric material layers within the semiconductor dies. In one embodiment, the trenches may be formed into a semiconductor substrate that includes semiconductor die substrates of the semiconductor dies. In this embodiment, the uniform depth may be less than the combined thickness of the dielectric layers and the semiconductor wafer. Alternatively, the trenches may be formed as gaps between neighboring pairs of semiconductor dies that are placed over a carrier substrate during manufacture of a reconstituted wafer.

The trenches may be filled with an elastic dielectric fill material. Subsequently, the combination of the semiconductor dies and a grid-shaped portion of the elastic dielectric fill material may be diced along the dicing channels, resulting in individual semiconductor dies each encased in an elastic protective material portion of the elastic dielectric fill material. The elastic protective material portion mitigates mechanical stress during subsequent handling and packaging steps, thereby enhancing the overall reliability of the semiconductor packages. The elastic dielectric fill material may be selected from materials such as silicon oxide, silicon carbide, boron carbide, molding compound materials, and various polymers, providing a range of mechanical properties to suit different application requirements.

In one embodiment, the diced semiconductor dies may be attached to a packaging structure using an array of solder material portions. An underfill material with a Young's modulus lower than that of the elastic dielectric fill material may be applied around the solder material portions. Use of materials having different Young's moduli further enhances mechanical protection and stress relief for the semiconductor package. In one embodiment, the elastic dielectric fill material may have a first Young's modulus ranging from 10 GPa to 90 GPa, and the underfill material may have a second Young's modulus ranges from 3 GPa to 10 GPa, ensuring a balance between rigidity and flexibility.

The device structure provided by this manufacturing method may include a semiconductor die with a substrate, semiconductor devices, metal interconnect structures embedded within dielectric material layers, and an elastic protective material portion. This frame surrounds the dielectric layers and upper portions of the die substrate, effectively reducing the risk of mechanical damage. The width of each elastic protective material portion may be in a range from 1 micron to 300 microns, and the height of each elastic protective material portion may be in a range 5 microns to 600 microns.

Embodiments of the present disclosure offer several advantages, which include enhanced mechanical protection during temperature cycling and multiple reflow processes, improved reliability of the semiconductor packages, and scalability for various semiconductor technology generations. Embodiments of the present disclosure may be adapted for different packaging configurations, thereby providing a robust solution to the mechanical challenges faced in semiconductor manufacturing. Embodiments of the present disclosure may improve the performance and durability of semiconductor devices to meet rigorous demands of modern electronic applications. The various aspects and embodiments of the methods and structures of the present disclosure are described with reference to accompanying drawings herebelow.

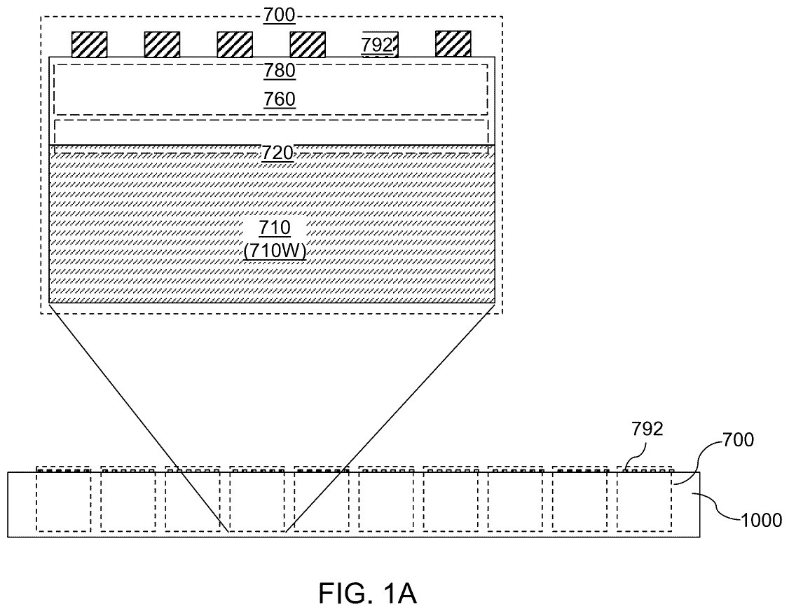

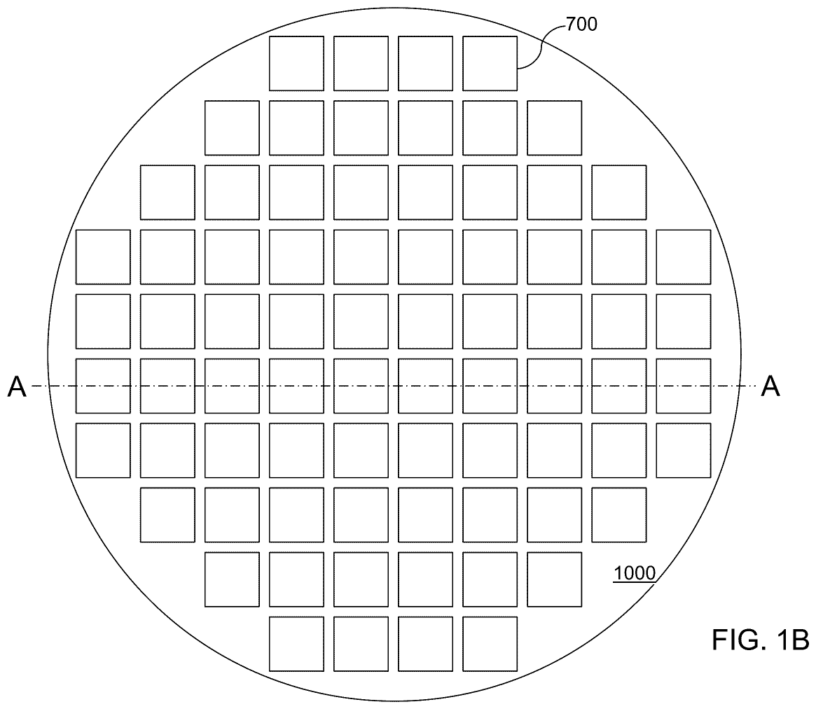

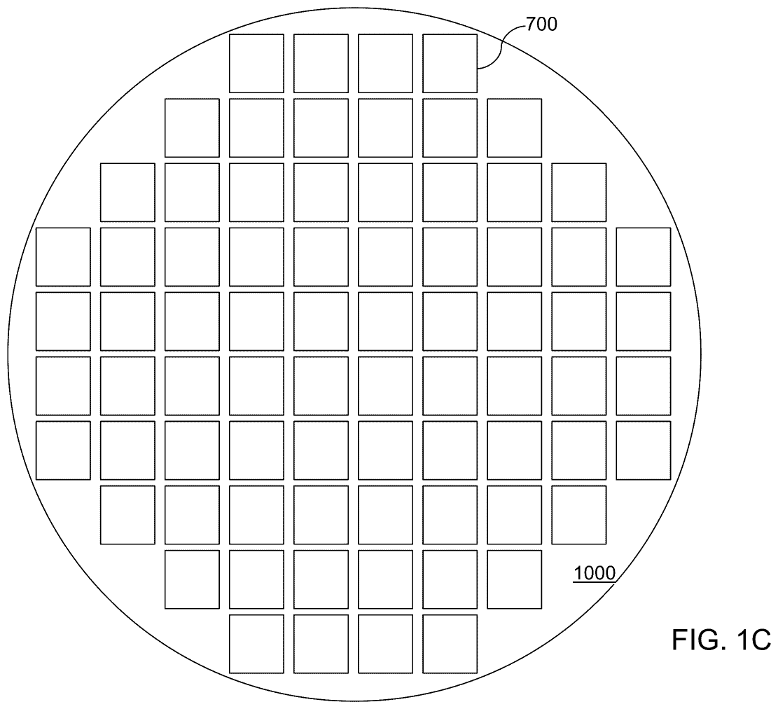

Referring to FIGS. 1A and 1B, a first exemplary structure according to a first embodiment of the present disclosure is illustrated. The first exemplary structure comprises a device wafer 1000 containing a two-dimensional array of semiconductor dies 700. The device wafer 1000 comprises a semiconductor substrate 710W, which may be a semiconductor wafer such as a single crystalline silicon wafer. Each semiconductor die 700 comprises a respective portion of the semiconductor substrate 710W. The semiconductor dies 700 are adjoined among one another by a rectangular grid of dicing channel regions, which may comprise first dicing channel regions that laterally extend along a first horizontal direction and second dicing channel regions that laterally extend along a second horizontal direction that is perpendicular to the first horizontal direction.

Generally, the first exemplary structure may comprise a semiconductor substrate 710W, and the two-dimensional array of semiconductor dies 700 comprises portions of the semiconductor substrate 710W that is enclosed by areas of the dicing channel regions. Each portion of the semiconductor substrate 710W that is located within a semiconductor die 700 is herein referred to as a semiconductor die substrate 710. Each semiconductor die 700 may comprise semiconductor devices 720 located on the semiconductor die substrate 710, metal interconnect structures 780 formed within dielectric material layers 760 and electrically connected to the metal interconnect structures 780, and metal bump structures 792 located on a topmost dielectric material layer among the dielectric material layers 760. According to an aspect of the present disclosure, neighboring pairs of semiconductor dies 700 may be laterally spaced from each other by a lateral spacing that is greater than the width of a dicing channel to be subsequently used along each direction of periodicity on the semiconductor substrate 710W.

The semiconductor devices 720 may comprise field effect transistors, diodes, capacitors, resistors, radio-frequency switching devices, memory cells, photonic devices, and/or any other type of semiconductor devices known in the art. The dielectric material layers 760 may comprise, and/or may consist of, inorganic dielectric materials such as silicate glasses, silicon nitride, silicon carbide nitride, silicon oxynitride, dielectric metal oxides, etc. It is noted that organosilicate glass is primarily composed of inorganic silicon-oxygen bonds, and thus, despite presence of some C—H bonds, organosilicate glass is an inorganic material despite its name. In one embodiment, the dielectric material layers 760 may be free of polymer materials. Alternatively, a polymer layer (such as a polyimide layer) may be used at the topmost level of the dielectric material layers 760. The metal interconnect structures 780 may comprise metal line structures, metal pad structures, and/or metal via structures. The metal interconnect structures 780 may comprise tungsten, copper, and/or aluminum. Each semiconductor die 700 may comprise a two-dimensional array of metal bump structures 792, which may be configured as microbump structures (such as copper pillars configured for chip connection bonding), or bonding pads (such as controlled-collapse chip connection (C4) bonding pads).

Referring to FIG. 1C, an alternative embodiment of the first exemplary structure may be derived from the first exemplary structure of FIGS. 1A and 1B by using a lateral spacing that is greater than the width of a dicing channel to be subsequently employed for neighboring semiconductor dies 700 that are laterally spaced apart from one another along a first repetition direction for the semiconductor dies 700, and by using a lateral spacing that equals the width of a dicing channel to be subsequently used for semiconductor dies 700 that are laterally spaced apart from one another along a second repetition direction for the semiconductor dies 700.

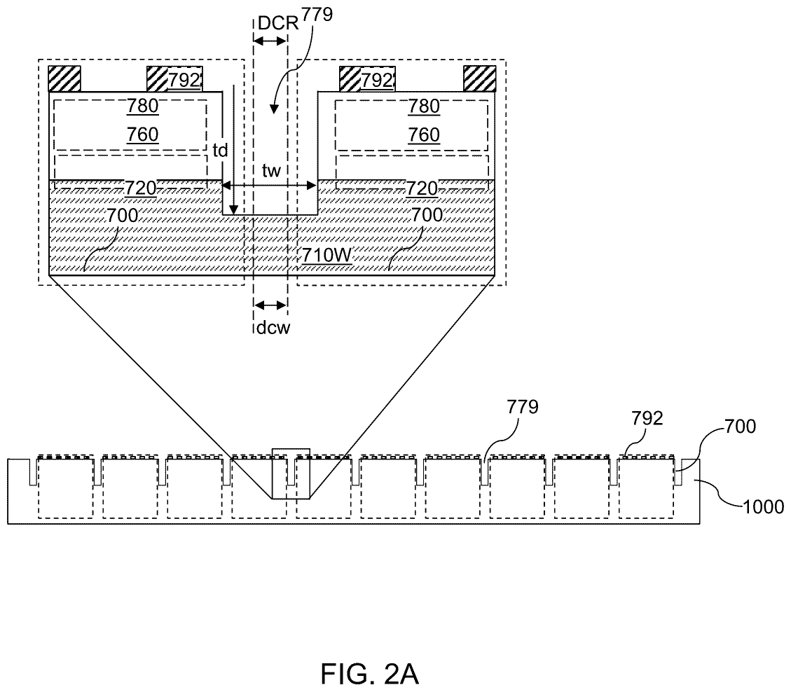

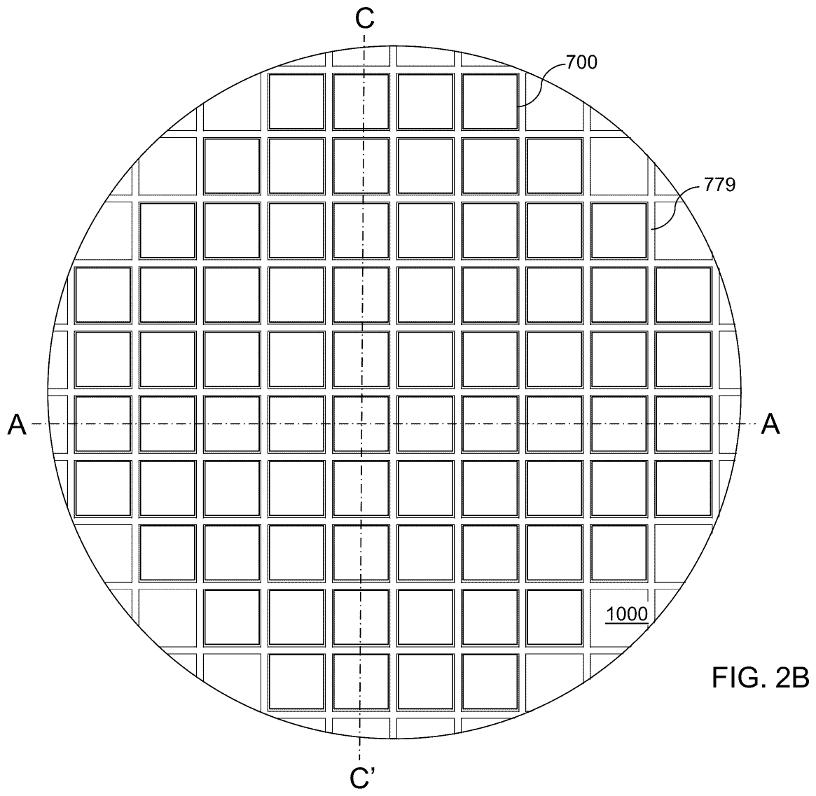

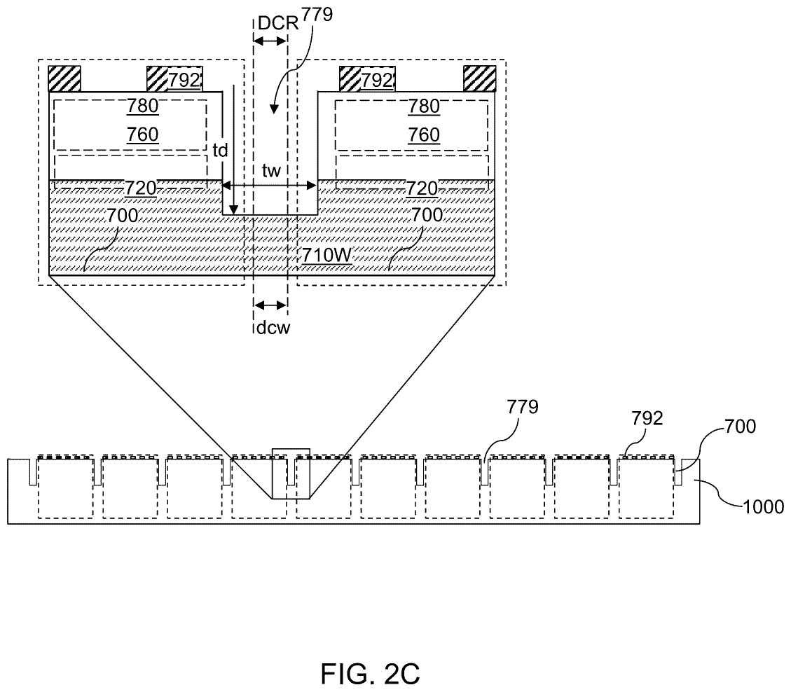

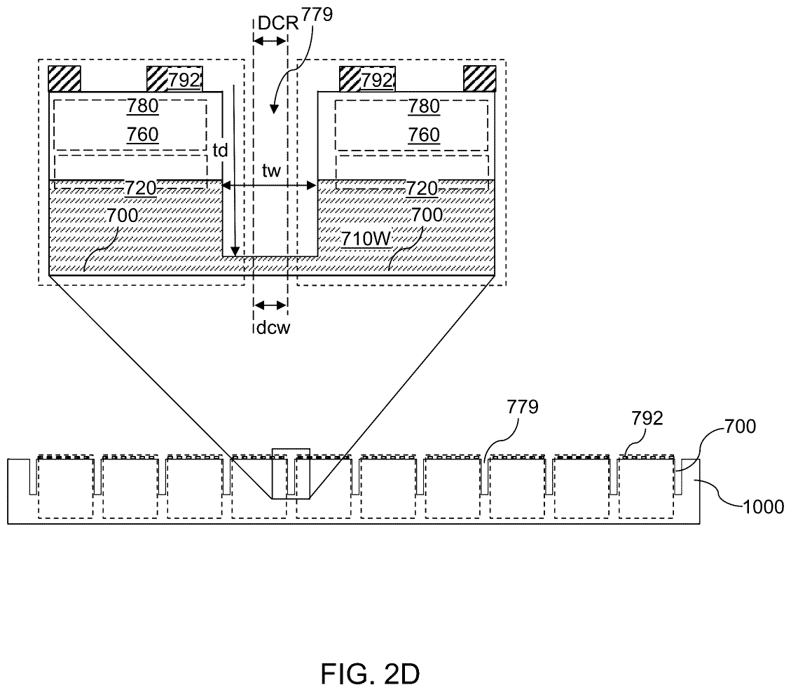

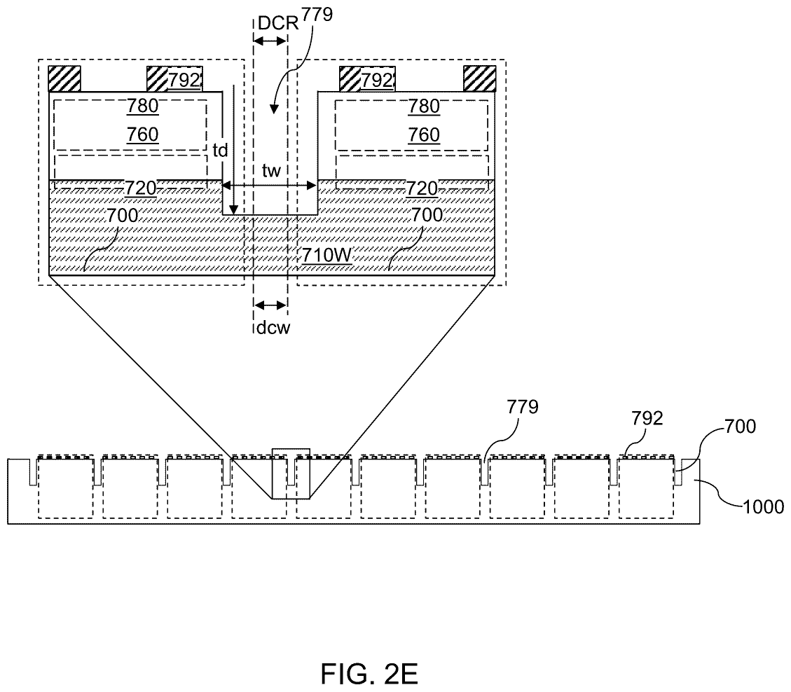

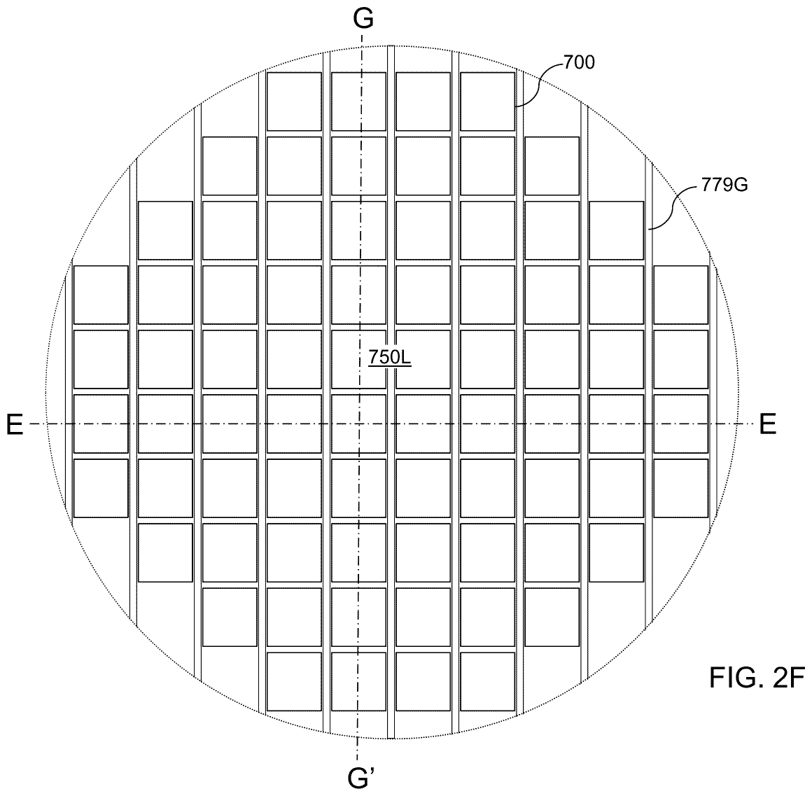

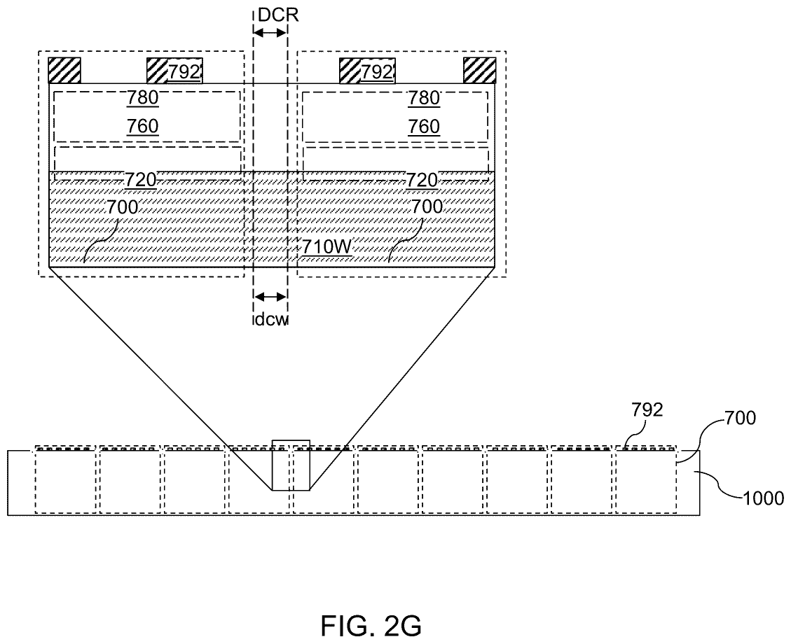

Referring to FIGS. 2A-2C, a rectangular grid of trenches 779 may be formed in the device wafer 1000. For example, a photoresist layer (not shown) may be applied over the top surface of the device wafer 1000, and may be lithographically patterned to form a rectangular grid of interconnected laterally-extending openings therein. The areas of openings in the photoresist layer include all of the areas of the dicing channel regions DCR and adjacent areas of the semiconductor dies 700. The dicing channel regions DCR are regions from which material are removed during a subsequent dicing process. As discussed above, the dicing channel regions DCR may comprise first dicing channel regions that laterally extend along the first horizontal direction with a dicing channel width dew along the second horizontal direction, and second dicing channel regions that laterally extend along the second horizontal direction with the dicing channel width dew along the first horizontal direction. The dicing channel width dew may be in a range from 30 microns to 150 microns, such as from 50 microns to 120 microns, although lesser and greater uniform widths may also be used.

The areas of the laterally-extending openings in the photoresist layer overlap with areas of peripheral regions of the semiconductor dies 700. An anisotropic etch process may be performed to etch through the entirety of unmasked portions of the dielectric material layers 760 that underlie the rectangular grid of interconnected laterally-extending openings, and to etch an upper portion of the semiconductor substrate 710W. The rectangular grid of trenches 779 is formed in the volumes from which the materials of the device wafer 1000 are removed underneath the rectangular grid of interconnected laterally-extending openings in the photoresist layer. According to an aspect of the present disclosure, the rectangular grid of trenches 779 may be formed by removing a semiconductor material of the semiconductor substrate 710W within a grid-shaped area between a top surface of the semiconductor substrate 710W and a horizontal plane located between the top surface of the semiconductor substrate 710W and a bottom surface of the semiconductor substrate 710W. The photoresist layer may be subsequently removed, for example, by ashing.

A recessed surface of the semiconductor substrate 710W is physically exposed at a bottom of each of the trenches 779. The trenches are interconnected among one another to provide the rectangular grid of interconnected and intersecting trenches 779. The rectangular grid of trenches 779 has a uniform depth that is greater than a total thickness of the dielectric material layers 760, and is less than the sum of the total thickness of the dielectric material layers 760 and the thickness of the semiconductor substrate 710W. The depth of the rectangular grid of trenches 779 is herein referred to as a trench depth td. The trench depth td is the vertical distance between the horizontal plane including the topmost surface of the dielectric material layers 760 and the physically exposed recessed horizontal surface of the semiconductor substrate 710W that underlies the rectangular grid of trenches 779. In an illustrative example, the total thickness of the dielectric material layers 760 may be in a range from 2 microns to 20 microns, and the thickness of the semiconductor substrate 710W may be in a range from 500 microns to 1,000 microns. The trench depth td may be in a range from 5 microns to 600 microns, such as from 10 microns to 300 microns, and/or from 15 microns to 100 microns, although lesser and greater thicknesses may also be used.

Each trench 779 has a trench width tw that is greater than the dicing channel width dcw. The difference between the trench width tw and the dicing channel width dew determines the lateral width of elastic dielectric frames to be subsequently formed around each semiconductor die 700. Specifically, the lateral width (i.e., the lateral distance between a neighboring pair of an inner sidewall and an outer sidewall) of each elastic dielectric frame to be subsequently formed is about one half of the difference between the trench width tw and the dicing channel width dcw. The lateral width of the elastic dielectric frames may be in a range from 1 micron to 300 microns, although lesser and greater lateral widths may also be used. Correspondingly, the trench width tw may be greater than the dicing channel width dew by a width differential in a range from 2 microns to 600 microns.

Generally, a structure including a two-dimensional array of semiconductor dies 700 and a rectangular grid of trenches 779 that laterally extend along dicing channel regions DCR may be provided. The trenches 779 are wider than the width of each of the dicing channel regions DCR.

Referring to FIG. 2D, a first alternative configuration for the first exemplary structure may be derived from the first exemplary structure illustrated in FIGS. 2A-2C by increasing the trench depth td such that the bottom surfaces of the trenches 779 are formed at, or below, a horizontal plane in which a thinned backside surface of the semiconductor substrate 710W is to be subsequently formed upon thinning.

Referring to FIGS. 2E-2G, a second alternative configuration for the first exemplary structure may be derived from the first exemplary structure or from the first alternative configuration of the first exemplary structure by forming the trenches 779G only along one vertical direction without forming the trenches 779 along another horizontal direction. Specifically, the trenches 779 may be formed only between neighboring pairs of semiconductor dies 700 that are laterally spaced from each other by a lateral spacing that is greater than the width of a dicing channel.

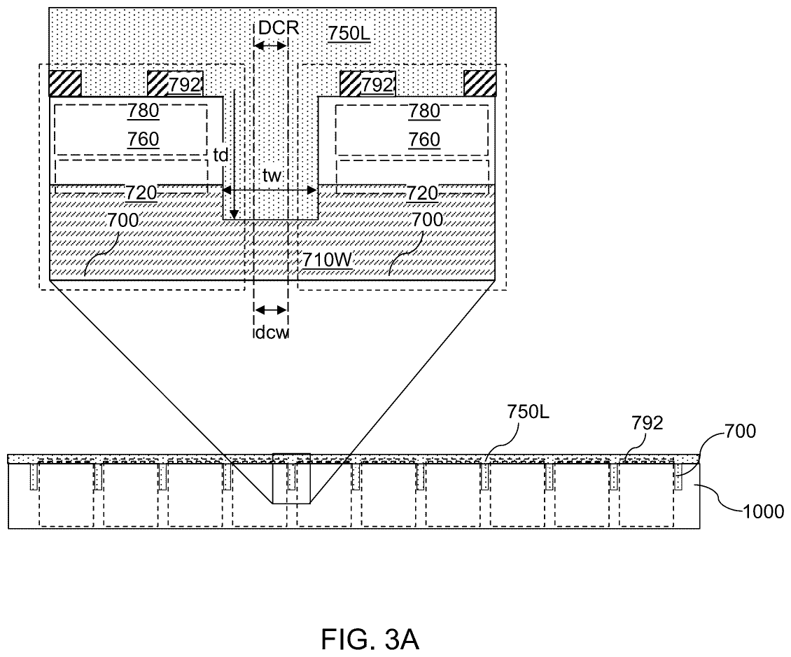

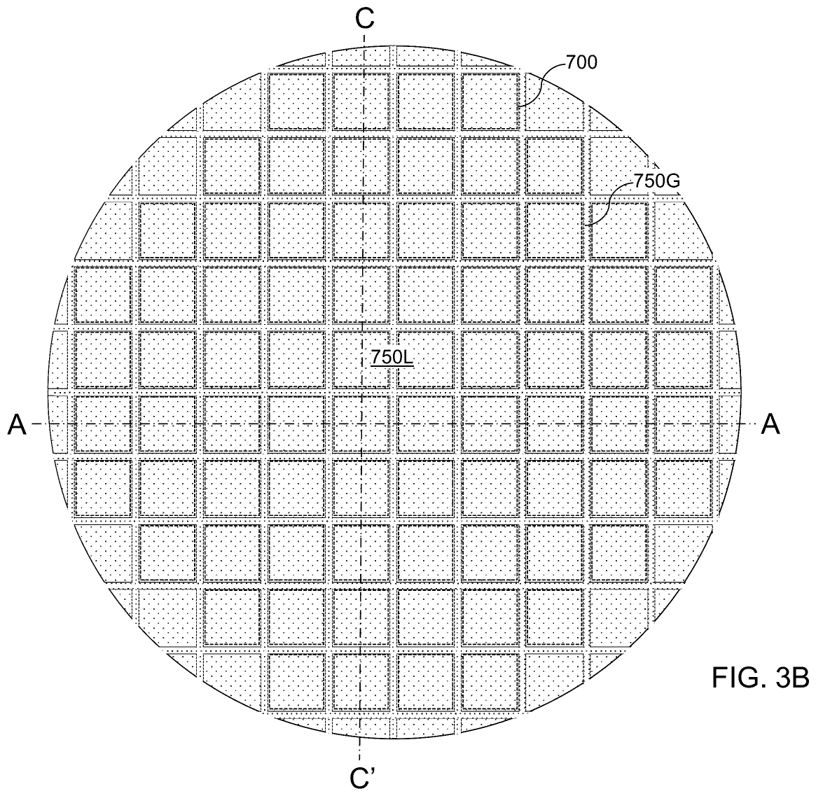

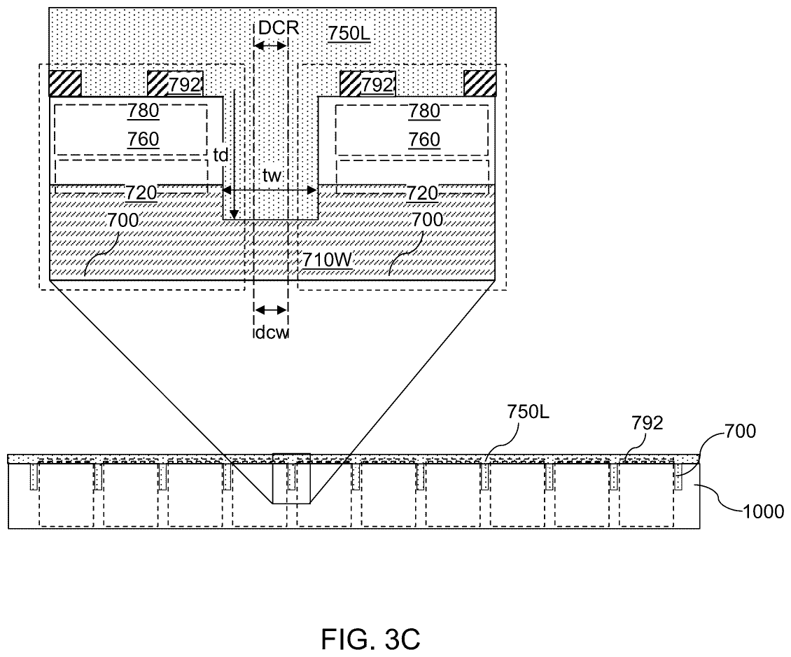

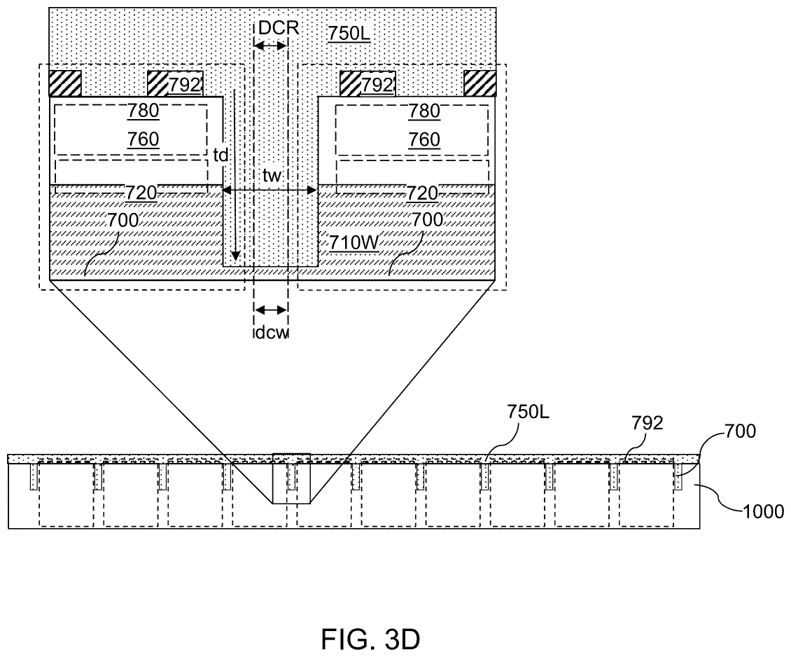

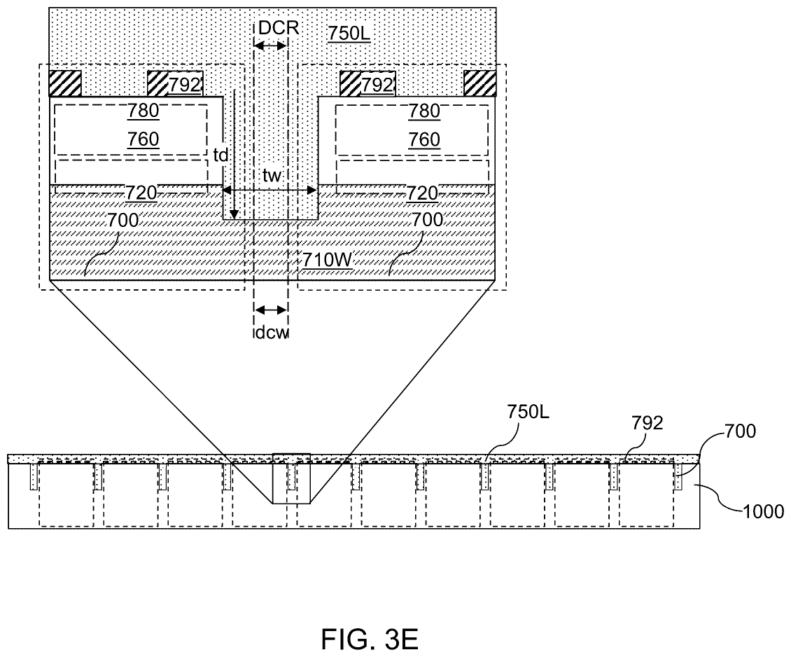

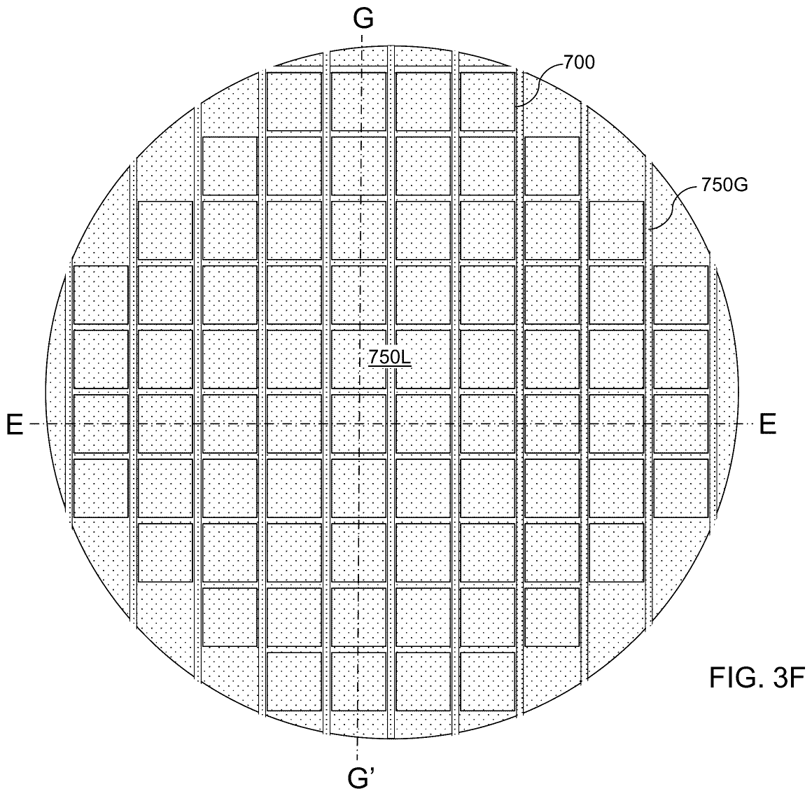

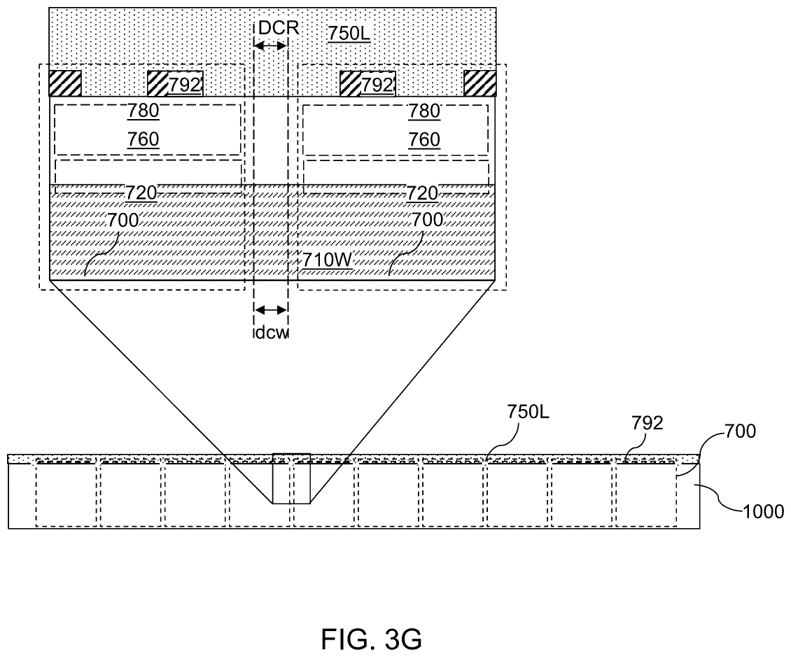

Referring to FIGS. 3A-3C, an elastic dielectric fill material may be deposited in the rectangular grid of trenches 779. As used herein, an “elastic material” refers to a material having a Young's modulus not greater than 90 GPa. The elastic dielectric fill material may be deposited by a conformal deposition process or by a self-planarizing deposition process (such as spin coating) in a pre-cure state followed by a curing process. The elastic dielectric fill material forms an elastic dielectric material layer 750L that fills the rectangular grid of trenches 779 and extends over the topmost surface of the dielectric material layers 760 and the metal bump structures 792. The thickness of a horizontally-extending portion of the elastic dielectric material layer 750L above the dielectric material layers 760 between neighboring pairs of metal bump structures 792 may be in a range from 50 microns to 500 microns, depending on the process used to form the elastic dielectric material layer 750L.

According to an aspect of the present disclosure, the elastic dielectric fill material has a first Young's modulus that is greater than a second Young's modulus of an underfill material layer to be subsequently used to laterally surround an array of solder material portions used to effect a solder-mediated bonding on the metal bump structures 792. In one embodiment, the first Young's modulus of the elastic dielectric fill material of the elastic dielectric material layer 750L may be in a range from 10 GPa to 90 GPa, and/or in a range from 10 GPa to 50 GPa, and/or in a range from 15 GPa to 40 GPa; and the second Young's modulus of the underfill material to be subsequently used to form an underfill material portion around solder material portions may be in a range from 2.5 GPa to 10 GPa, such as from 3 GPa to 8 GPa.

Non-limiting examples of elastic dielectric fill materials that may be used to form the elastic dielectric material layer 750L include silicon oxide, silicon carbide, boron carbide, molding compound materials, polymer materials, and stiff underfill materials having a Young's modulus greater than 10 GPa. Silicon oxide materials, such as undoped silicate glass and doped silicate glasses, have Young's moduli of about 70 GPa. Silicon carbide has a Young's modulus in a range from 70 GPa to 75 GPa. Boron carbide has a Young's modulus in a range from 50 GPa to 70 GPa. Molding compound materials such as epoxy have Young's moduli in a range from 10 GPa to 20 GPa.

While most polymers have Young's moduli less than 10 GPa, some polymers may provide Young's moduli in a range from 10 GPa to 90 GPa by incorporating stiff composites and high-modulus fillers. For example, carbon fiber reinforced polymers (CFRP) may have a Young's modulus in a range from 70 GPa to 90 GPa (or higher depending on the percentage of the carbon fiber); graphene reinforced polymers may provide a Young's modulus in a range from 50 GPa to 90 GPa (or higher depending on the percentage of graphene); glass-filled epoxy resin has a Young's modulus in a range from 10 GPa to 20 GPa; and phenol formaldehyde resins filled with mica have a Young's modulus in a range from 38 GPa to 50 GPa.

Related underfill materials have Young's moduli ranging from 2.5 GPa to 10 GPa. To achieve higher stiffness, stiff underfill materials that may be used for the elastic dielectric material layer 750L have Young's moduli ranging from 10 GPa to 90 GPa. Various techniques may be utilized to increase the Young's modulus of these materials. According to an aspect of the present disclosure, high-modulus fillers may be added to the polymer matrix of an underfill material to increase its Young's modulus. Common fillers include silica, alumina, carbon nanotubes (CNTs), and boron nitride (BN). For instance, adding high-purity, finely dispersed silica may enhance the modulus. Carbon nanotubes, known for their exceptional mechanical properties, may also be incorporated to boost stiffness. Alumina and boron nitride serve similar purposes by improving the overall mechanical properties of the underfill materials.

Alternatively or additionally, the cross-linking density of the polymer matrix of the underfill material may be increased, which in turn may increase the Young's modulus of an underfill material. For example, the cross-linking density of the underfill material may be increased by using higher concentrations of cross-linking agents during the formulation process. Additionally, optimizing the curing process, such as adjusting the temperature and duration, ensures maximum cross-linking, thereby enhancing the material's stiffness. Further, hybrid materials and/or nanocomposites may be used to increase the Young's modulus of an underfill material to be used for the elastic dielectric material layer. Combining organic polymers with inorganic components, such as in polymer-silica hybrids, creates a more rigid network in the underfill material. Incorporating nanomaterials like nano-silica or graphene oxide may further improve the stiffness due to their high surface area and superior mechanical properties.

For example, glass-filled epoxy resins have Young's moduli ranging from 10 GPa to 20 GPa, phenol formaldehyde resins filled with mica have moduli in the range of 38 GPa to 50 GPa, and melamine formaldehyde resins filled with fabric may achieve moduli between 60 GPa and 90 GPa. Generally, through selection of filler materials and/or optimization of the cross-linking process and additional material modification techniques, it is possible to increase the Young's modulus of underfill materials to a range from 10 GPa to 90 GPa.

Referring to FIG. 3D, a first alternative configuration for the first exemplary structure may be derived from the first exemplary structure illustrated in FIGS. 3A-3C by increasing the trench depth td such that the bottom surfaces of the trenches 779 are formed at, or below, a horizontal plane in which a thinned backside surface of the semiconductor substrate 710W is to be subsequently formed upon thinning. As such, bottom surfaces of the elastic dielectric material layer 750L may be formed at, or below, the horizontal plane in which a thinned backside surface of the semiconductor substrate 710W is to be subsequently formed upon thinning.

Referring to FIGS. 3E-3G, a second alternative configuration for the first exemplary structure may be derived from the first exemplary structure or from the first alternative configuration of the first exemplary structure by forming the trenches 779 only along one horizontal direction without forming the trenches 779 along another horizontal direction. Specifically, the trenches 779 may be formed only between neighboring pairs of semiconductor dies 700 that are laterally spaced from each other by a lateral spacing that is greater than the width of a dicing channel. As such, the elastic dielectric material layer 750L laterally extend only along a single horizontal direction, and are parallel among one another.

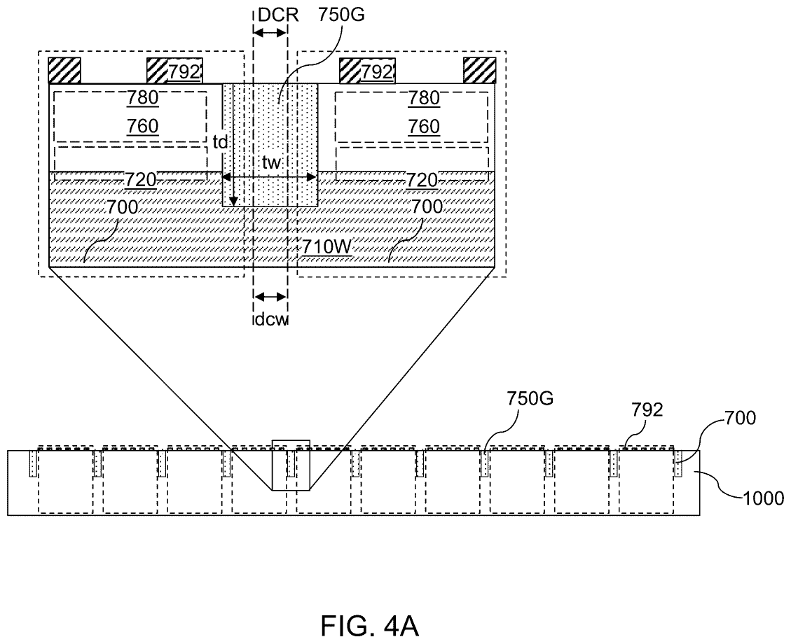

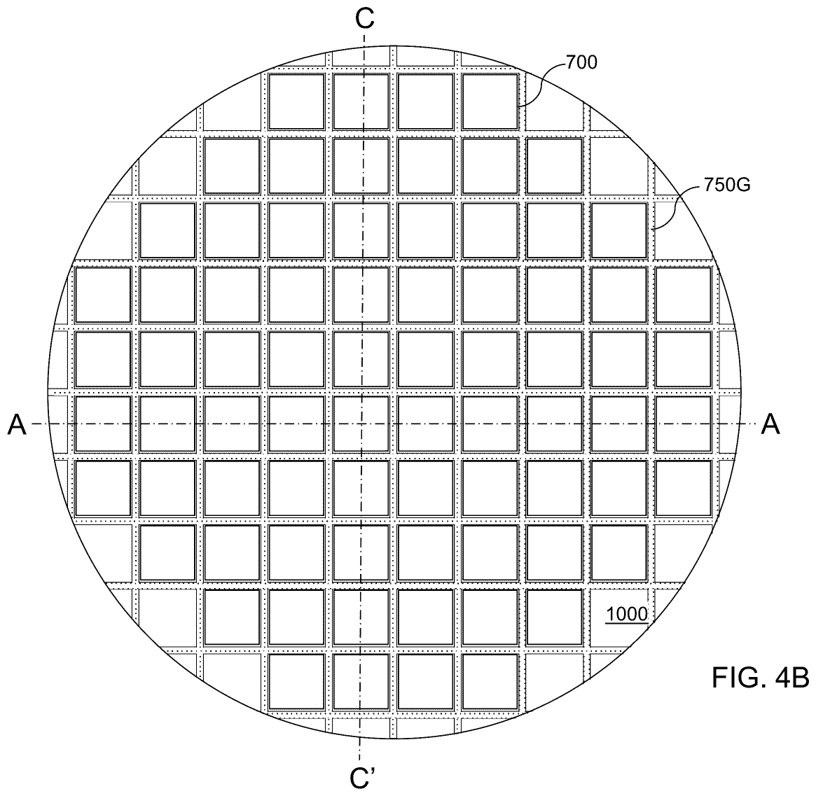

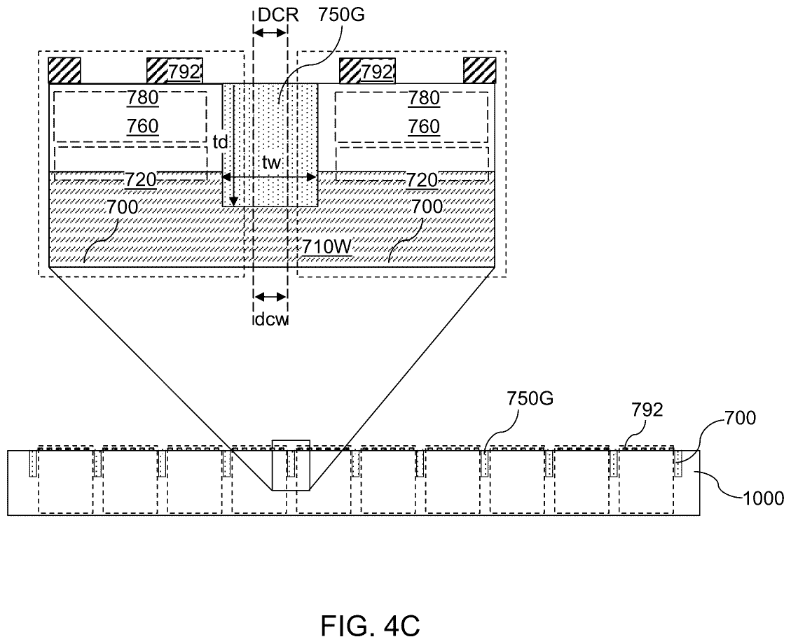

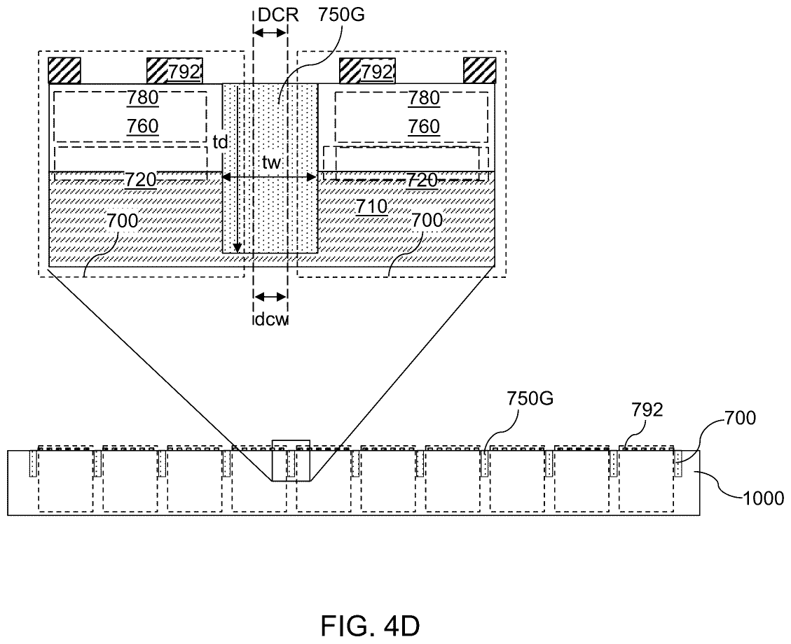

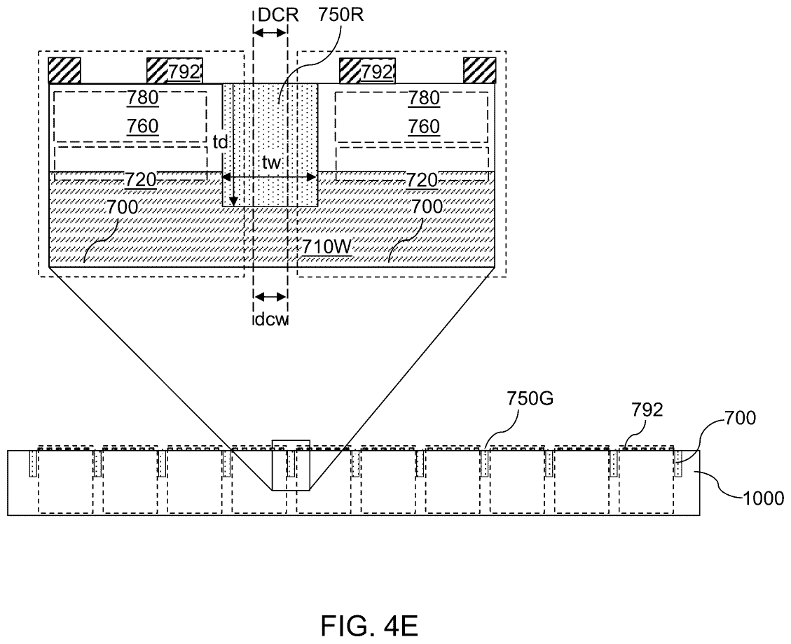

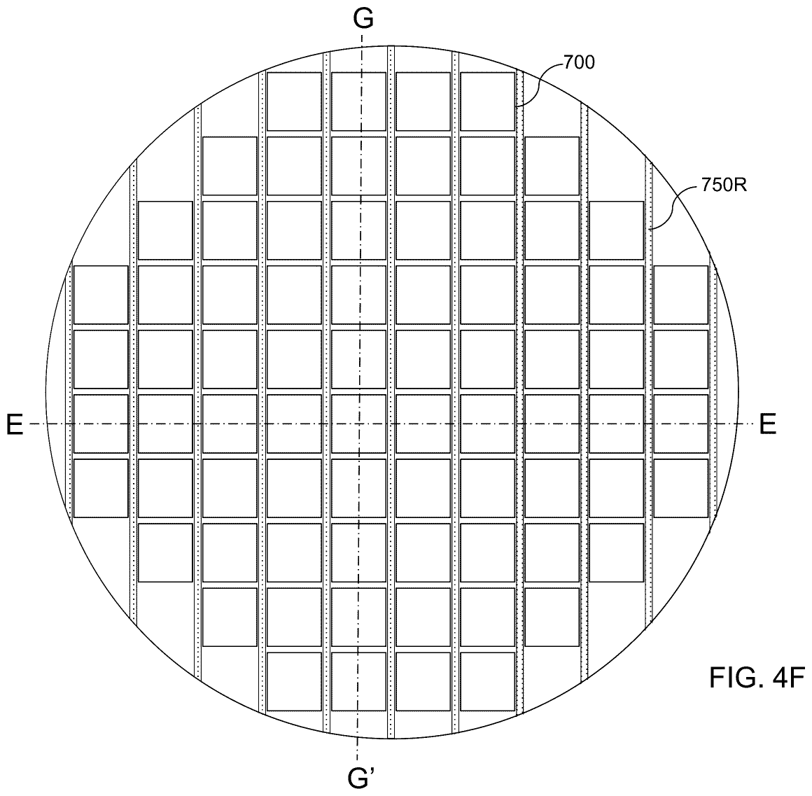

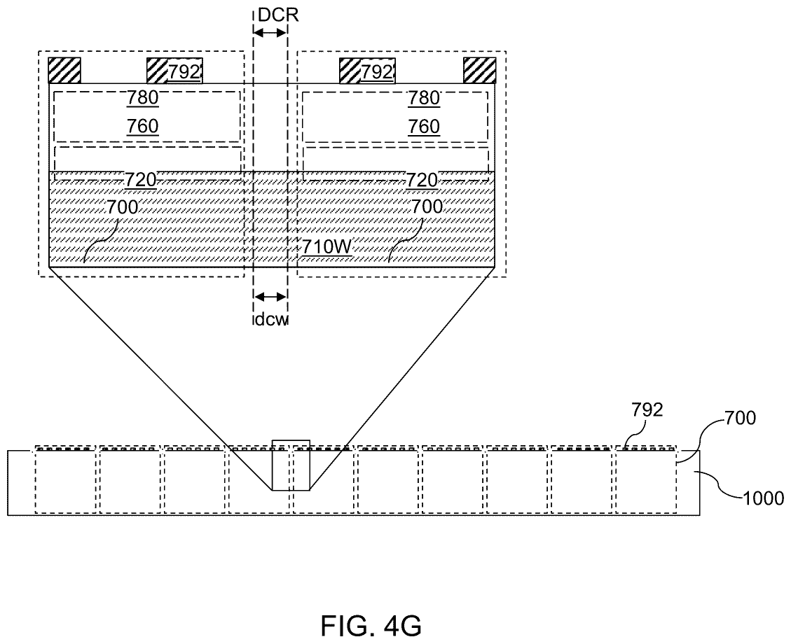

Referring to FIGS. 4A, 4B, and 4C, the horizontally-extending portion of the elastic dielectric material layer 750L overlying the horizontal plane including the topmost surface of the dielectric material layers 760 may be removed. For example, an isotropic etch process, an anisotropic etch process, and/or a chemical mechanical polishing process may be performed to remove the horizontally-extending portion of the elastic dielectric material layer 750L from above the horizontal plane including the topmost surface of the dielectric material layers 760.

Generally, portions of the elastic dielectric fill material located outside the trenches 779 may be removed, while portions of the elastic dielectric fill material located inside the trenches 779 are not removed. The remaining portion of the elastic dielectric fill material in the trenches 779 comprise a grid network of elastic dielectric fill material rails, which is herein referred to as an elastic dielectric fill material grid 750G. The elastic dielectric fill material grid 750G has a uniform depth that is greater than the total thickness of the dielectric material layers 760 within each of the elastically padded semiconductor dies (700, 750), and is less than the sum of the total thickness of the dielectric material layers 760 and the thickness of the semiconductor substrate 710W. In one embodiment, the elastic dielectric fill material grid 750G may have a height that is the same as, or is about, the trench depth td, and may have a width that is the same as the trench width tw.

Subsequently, the semiconductor substrate 710W may be thinned. For example, a handle substrate (not illustrated) may be attached to the front side of the device wafer 1000 (e.g., to the metal bump structures 792), and a backside removal process may be performed to remove a backside portion of the semiconductor substrate 710W. The backside removal process may comprise grinding, polishing, at least one isotropic etch process, and/or at least one anisotropic etch process. The thickness of the semiconductor substrate 710W as thinned may be less than, or equal to, the vertical extent of the elastic dielectric fill material grid 750G within the semiconductor substrate 710W. Thus, the bottom surfaces of the elastic dielectric fill material grid 750G may, or may not, be physically exposed upon thinning of the semiconductor substrate 710W. FIGS. 4A-4C illustrates a configuration in which the bottom surfaces of the elastic dielectric fill material grid 750G are not physically exposed upon thinning of the semiconductor substrate 710W. The handle substrate may be subsequently detached from the device wafer 1000, which includes a combination of the two-dimensional array of semiconductor dies 700 and the elastic dielectric fill material grid 750G.

Referring to FIG. 4D, a first alternative configuration for the first exemplary structure may be derived from the first exemplary structure illustrated in FIGS. 4A-4C by increasing the trench depth td such that the bottom surfaces of the trenches 779 may be formed at, or below, a horizontal plane in which a thinned backside surface of the semiconductor substrate 710W is to be subsequently formed upon thinning. As such, bottom surfaces of the elastic dielectric fill material grid 750G are formed at, or below, the horizontal plane in which a thinned backside surface of the semiconductor substrate 710W is to be subsequently formed upon thinning. The bottom surfaces of the elastic dielectric fill material grid 750G are physically exposed upon thinning of the semiconductor substrate 710W.

Referring to FIGS. 4E-4G , a second alternative configuration for the first exemplary structure may be derived from the first exemplary structure or from the first alternative configuration of the first exemplary structure by forming the trenches 779 only along one horizontal direction without forming the trenches 779 along another horizontal direction. The elastic dielectric material that fills the trenches 779 are formed as elastic dielectric material rails 750R that laterally extend along a same horizontal direction and do not intersect among one another. The bottom surfaces of the elastic dielectric material rails 750R may, or may not, be physically exposed depending on the depth of the elastic dielectric material rails 750R and depending on the location of the horizontal plane at which the thinned backside surface of the semiconductor substrate 710W is formed.

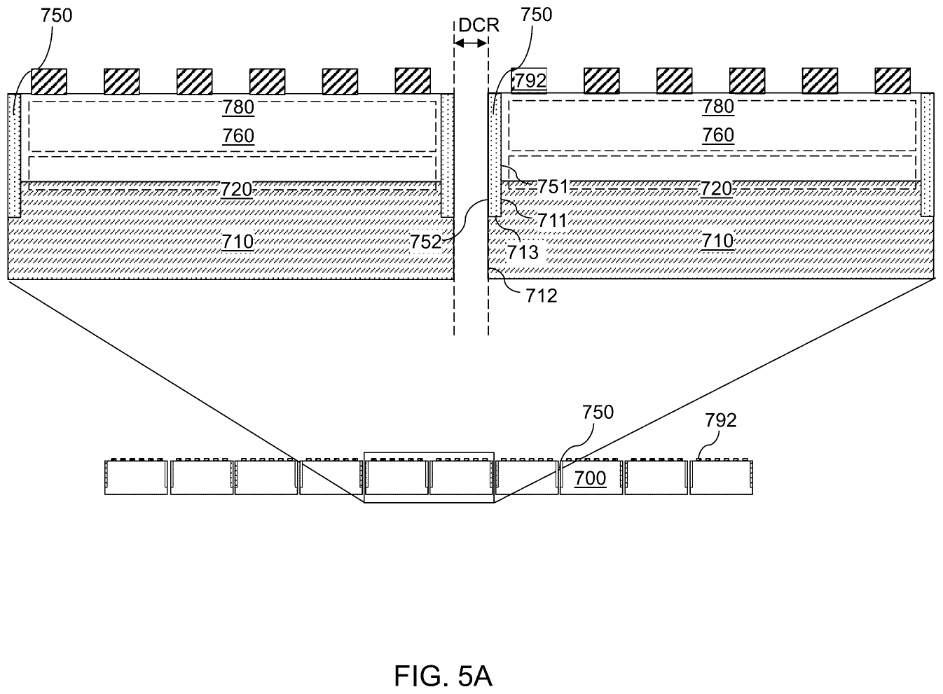

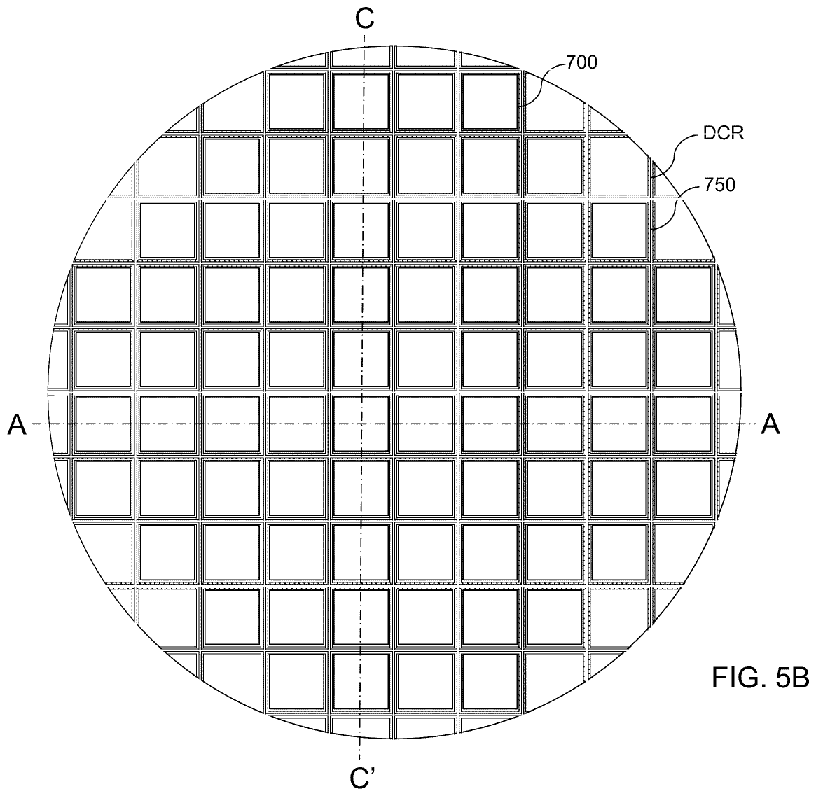

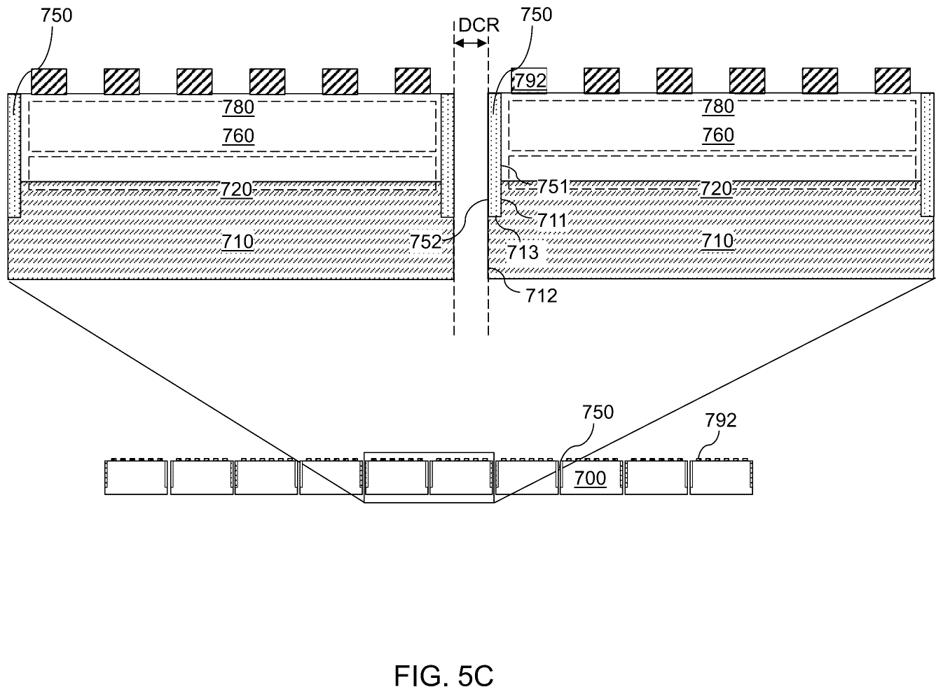

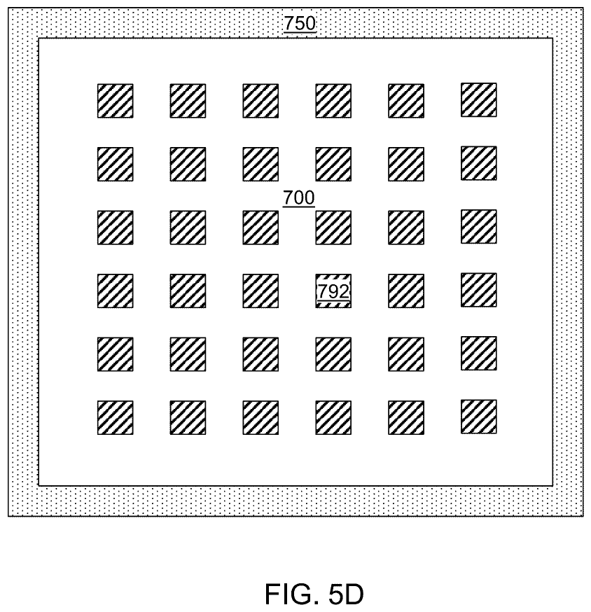

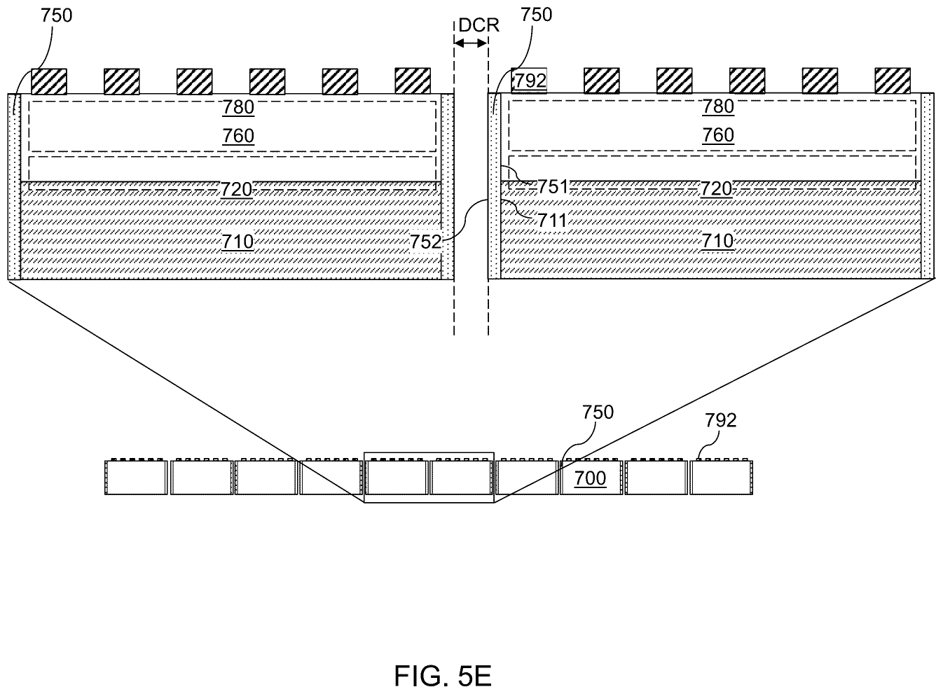

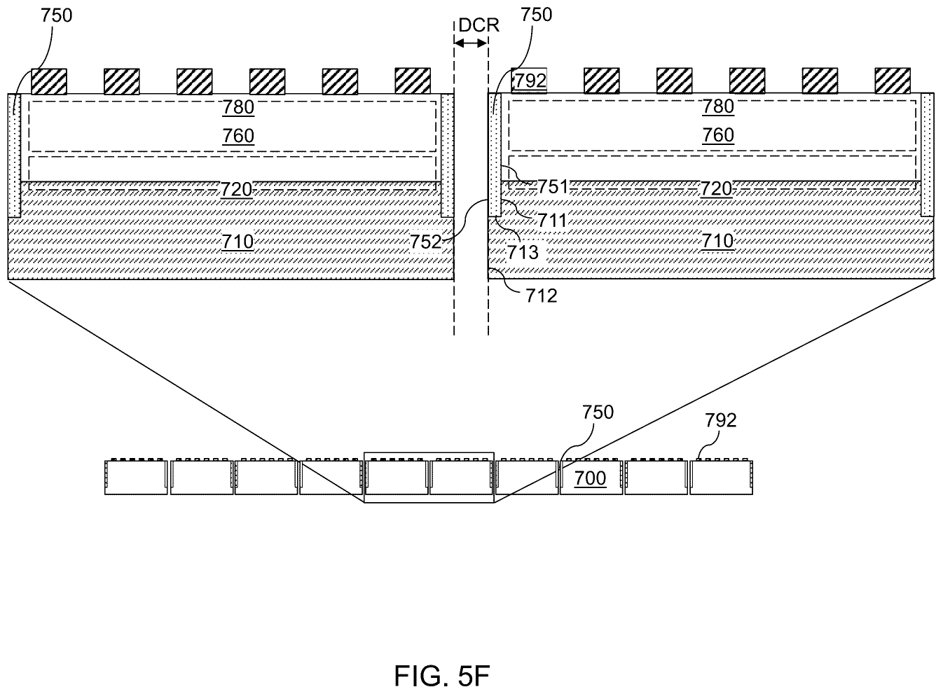

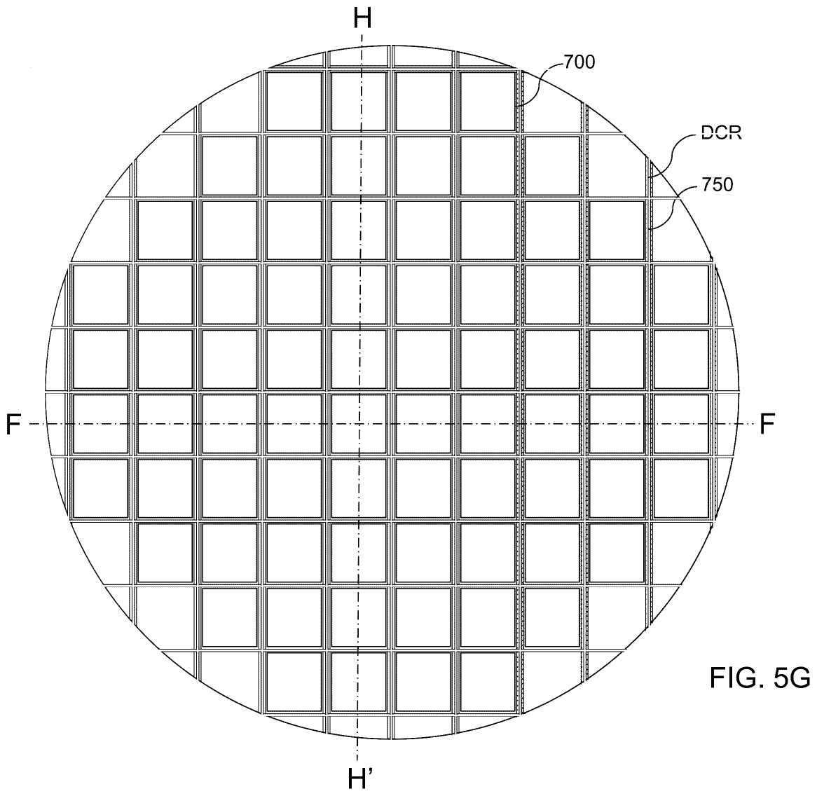

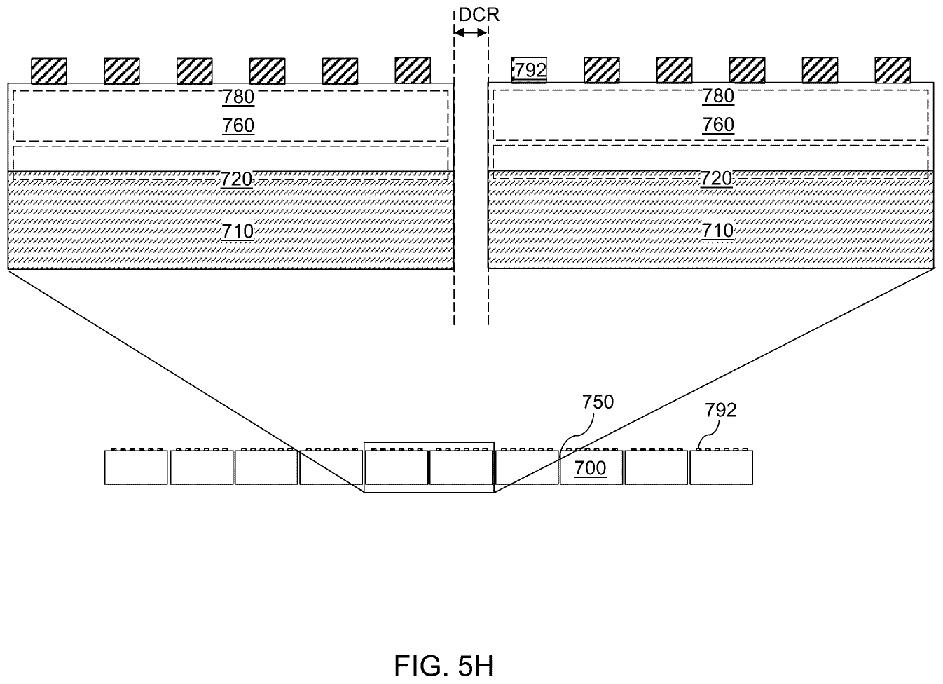

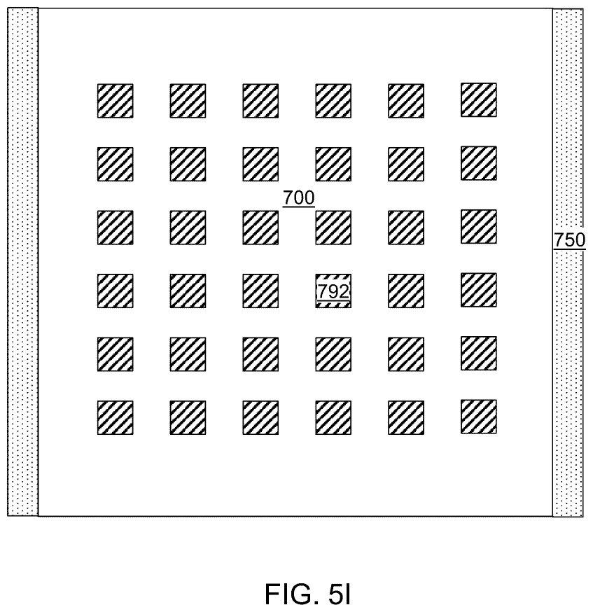

Referring to FIGS. 5A-5C , the device wafer 1000 may be diced into a plurality of elastically padded semiconductor dies (700, 750). Generally, the combination of the two-dimensional array of semiconductor dies 700 and a grid-shaped portion of the elastic dielectric fill material filling the rectangular grid of trenches 779 may be diced along the dicing channel regions DCR. The volume of the dicing channel regions DCR corresponds to the volume of materials that are removed during the dicing process. A plurality of singulated semiconductor dies (700, 750) is formed. Each singulated semiconductor die (700, 750) comprises a portion of the elastic dielectric fill material having a shape of a rectangular frame. As such, each singulated semiconductor die (700, 750) is an elastically padded semiconductor die (700, 750) comprising a combination of a semiconductor die 700 and an elastic protective material portion 750. Thus, a plurality of elastically padded semiconductor dies (700, 750) is formed

Each of the elastically padded semiconductor dies (700, 750) comprises a respective singulated semiconductor die (700, 750) that includes semiconductor devices 720 and metal bump structures 792 located on dielectric material layers 760, and further comprises an elastic protective material portion 750 comprising a portion of the elastic dielectric fill material and laterally surrounding the dielectric material layers 760. Each of the singulated semiconductor dies (700, 750) comprises a respective diced portion of the semiconductor substrate 710W, i.e., a semiconductor die substrate 710. Thus, each of the singulated semiconductor dies (700, 750) comprises a respective semiconductor die substrate 710 having a same material composition and a same thickness as the semiconductor substrate 710W.

In one embodiment, each elastically padded semiconductor die (700, 750) comprises: a semiconductor die substrate 710; semiconductor devices 720 located on the semiconductor die substrate 710; metal interconnect structures 780 formed within dielectric material layers 760 and electrically connected to the metal interconnect structures 780; metal bump structures 792 located on a topmost dielectric material layer among the dielectric material layers 760; and an elastic protective material portion 750 comprising an elastic dielectric fill material and laterally surrounding the dielectric material layers 760 and at least an upper portion of the semiconductor die substrate 710.

In one embodiment, each semiconductor die substrate 710 in an elastically padded semiconductor die (700, 750) may comprise: a set of first sidewalls 711 in contact with inner sidewalls 751 of the elastic protective material portion 750; a set of second sidewalls 712 adjoined to, and are vertically coincident with, outer sidewalls 752 of the elastic protective material portion 750; and a frame-shaped ledge surface 713 having an inner periphery that coincides with a periphery of the set of first sidewalls 711 and having an outer periphery that coincides with a boundary between the set of second sidewalls 712 and the outer sidewalls 752 of the elastic protective material portion 750. In one embodiment, the outer sidewalls 752 of the elastic protective material portion 750 in an elastically padded semiconductor die (700, 750) may be vertically coincident with (i.e., located within a same vertical plane as) the second sidewalls of semiconductor die substrate 710 of the elastically padded semiconductor die (700, 750). In one embodiment, the entirety of outer sidewalls of the dielectric material layers 760 may be in contact with the elastic protective material portion 750 within each elastically padded semiconductor die (700, 750). In one embodiment, each elastic protective material portion 750 may have a rectangular tubular configuration, and may be topologically homeomorphic to a torus. In this case, such elastic protective material portions 750 are referred to as elastic protective frames. The entirety of outer sidewalls of the dielectric material layers 760 may be located within vertical planes containing the first sidewalls 711 of the semiconductor die substrate 710.

Referring to FIG. 5D, a first alternative configuration for the first exemplary structure may be derived from the first exemplary structure illustrated in FIGS. 5A-5C by increasing the trench depth td such that the bottom surfaces of the elastic dielectric fill material grid 750G are physically exposed upon thinning of the semiconductor substrate 710W, and each elastically padded semiconductor die (700, 750) comprises an elastic protective material portion 750 having a frame-shaped bottom surface.

Referring to FIGS. 5E-5G, a second alternative configuration for the first exemplary structure may be derived from the first exemplary structure or from the first alternative configuration of the first exemplary structure by forming elastic dielectric material rails 750R that laterally extend along a same horizontal direction and do not intersect among one another in lieu of an elastic dielectric material grid 750G. In this case, each elastically padded semiconductor die (700, 750) comprises a pair of elastic protective material portion 750 located on opposite sides of a semiconductor die 700 and laterally spaced from each other. In this embodiment, each elastic protective material portion 750 may have a shape of a rectangular parallelopiped.

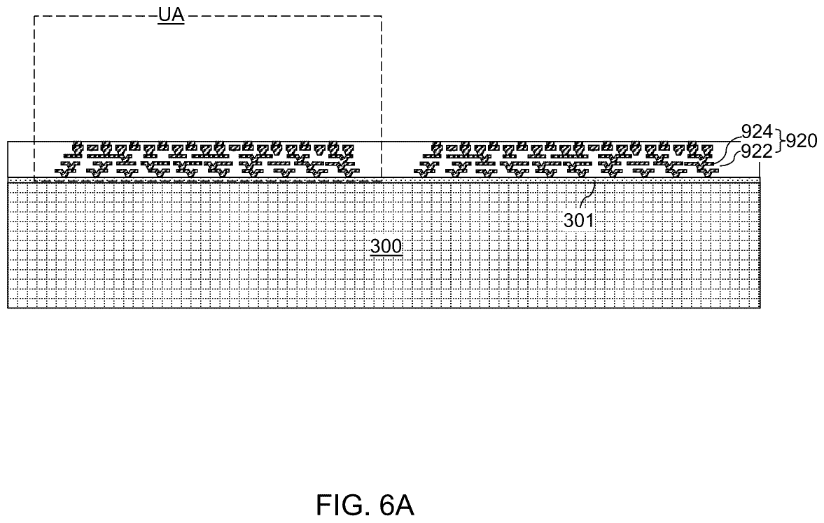

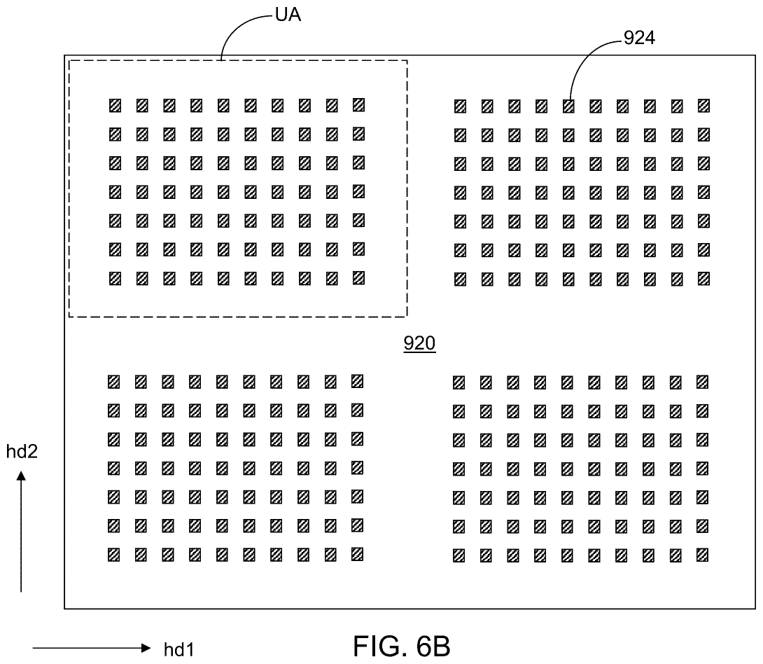

Referring to FIGS. 6A and 6B, a portion of a two-dimensional array of interposers 920 formed on a front surface of a first carrier wafer 300 is illustrated. The first carrier wafer 300 may include an optically transparent substrate such as a glass substrate or a sapphire substrate. The diameter of the first carrier wafer 300 may be in a range from 150 mm to 450 mm, although lesser and greater diameters may be used. In addition, the thickness of the first carrier wafer 300 may be in a range from 500 microns to 2,000 microns, although lesser and greater thicknesses may also be used. Alternatively, the first carrier wafer 300 may be provided in a rectangular panel format. The dimensions of the first carrier in such alternative embodiments may be substantially the same.

A first adhesive layer 301 may be applied to the front-side surface of the first carrier wafer 300. In one embodiment, the first adhesive layer 301 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 301 may include a thermally decomposing adhesive material. For example, the first adhesive layer 301 may include an acrylic pressure-sensitive adhesive that decomposes at an elevated temperature. The debonding temperature of the thermally decomposing adhesive material may be in a range from 150 degrees to 200 degrees Celsius.

An interposer 920 may be formed within each unit area UA, which is the area of a repetition unit that may be repeated in a two-dimensional array over the first carrier wafer 300. Each interposer 920 may include redistribution dielectric layers 922 and redistribution wiring interconnects 924. The redistribution dielectric layers 922 include a respective dielectric polymer material such as polyimide (PI), benzocyclobutene (BCB), or polybenzobisoxazole (PBO). Other suitable materials may be within the contemplated scope of disclosure. Each redistribution dielectric layer 922 may be formed by spin coating and drying of the respective dielectric polymer material. The thickness of each redistribution dielectric layer 922 may be in a range from 2 microns to 40 microns, such as from 4 microns to 20 microns. Each redistribution dielectric layer 922 may be patterned, for example, by applying and patterning a respective photoresist layer thereabove, and by transferring the pattern in the photoresist layer into the redistribution dielectric layer 922 using an etch process such as an anisotropic etch process. The photoresist layer may be subsequently removed, for example, by ashing.

Each of the redistribution wiring interconnects 924 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 400 nm, and the copper seed layer may have a thickness in a range from 100 nm to 500 nm. The metallic fill material for the redistribution wiring interconnects 924 may include copper, nickel, or copper and nickel. Other suitable metallic fill materials are within the contemplated scope of disclosure. The thickness of the metallic fill material that is deposited for each redistribution wiring interconnect 924 may be in a range from 2 microns to 40 microns, such as from 4 microns to 10 microns, although lesser or greater thicknesses may also be used. The total number of levels of wiring in each interposer 920 (i.e., the levels of the redistribution wiring interconnects 924) may be in a range from 1 to 10. A periodic two-dimensional array (such as a rectangular array) of interposers 920 may be formed over the first carrier wafer 300. Each interposer 920 may be formed within a unit area UA. The layer including all interposers 920 is herein referred to as an interposer layer. The interposer layer includes a two-dimensional array of interposers 920. In one embodiment, the two-dimensional array of interposers 920 may be a rectangular periodic two-dimensional array of interposers 920 having a first periodicity along a first horizontal direction hd1 and having a second periodicity along a second horizontal direction hd2 that is perpendicular to the first horizontal direction hd1.

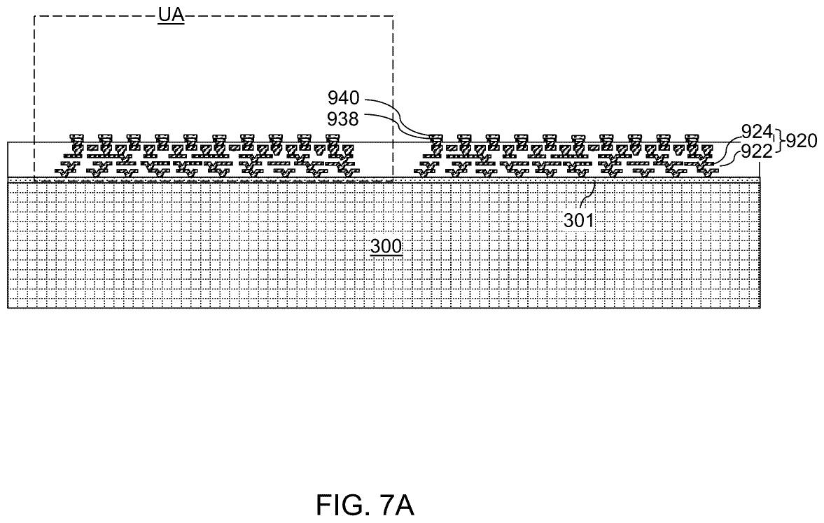

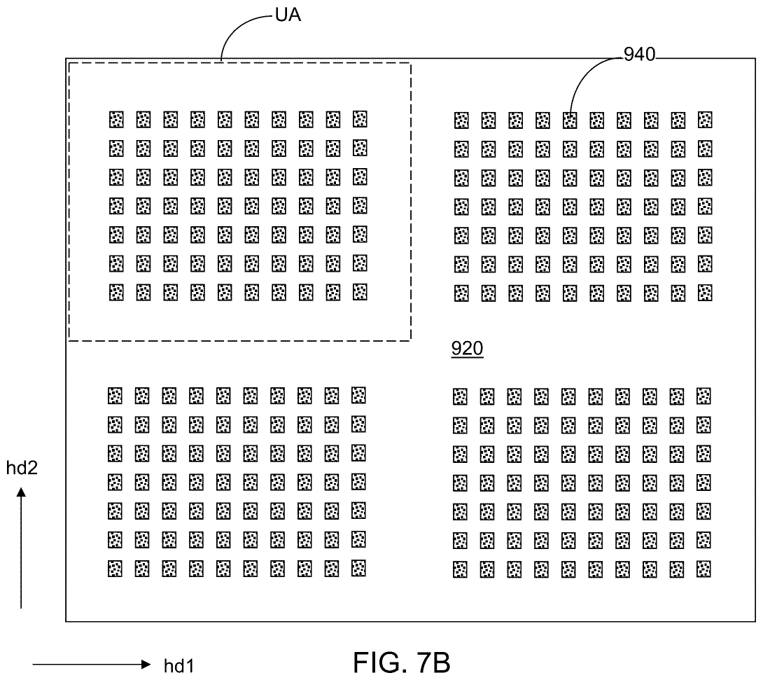

Referring to FIGS. 7A and 7B, at least one metallic material and a first solder material may be sequentially deposited over the front-side surface of the interposers 920. The at least one metallic material comprises a material that may be used for metallic bumps, such as copper. The thickness of the at least one metallic material may be in a range from 5 microns to 60 microns, such as from 10 microns to 30 microns, although lesser and greater thicknesses may also be used. The first solder material may comprise a solder material suitable for C2 bonding, i.e., for microbump bonding. The thickness of the first solder material may be in a range from 2 microns to 30 microns, such as from 4 microns to 15 microns, although lesser and greater thicknesses may also be used.

The first solder material and the at least one metallic material may be patterned into discrete arrays of first solder material portions 940 and arrays of metal bonding structures, which are herein referred to as arrays of interposer-side bonding structures 938. Each array of interposer-side bonding structures 938 is formed within a respective unit area UA. Each array of first solder material portions 940 is formed within a respective unit area UA. Each first solder material portion 940 may have a same horizontal cross-sectional shape as an underlying interposer-side bonding structures 938.

In one embodiment, the interposer-side bonding structures 938 may include, and/or may consist essentially of, copper or a copper-containing alloy. Other suitable materials are within the contemplated scope of disclosure. The thickness of the interposer-side bonding structures 938 may be in a range from 5 microns to 60 microns, although lesser or greater thicknesses may also be used. The interposer-side bonding structures 938 may have horizontal cross-sectional shapes of rectangles, rounded rectangles, circles, regular polygons, irregular polygons, or any other two-dimensional curvilinear shape having a closed periphery. In one embodiment, interposer-side bonding structures 938 may be configured for microbump bonding (i.e., C2 bonding), and may have a thickness in a range from 10 microns to 30 microns, although lesser or greater thicknesses may also be used. In this embodiment, each array of interposer-side bonding structures 938 may be formed as an array of microbumps (such as copper pillars) having a lateral dimension in a range from 10 microns to 25 microns, and having a pitch in a range from 20 microns to 50 microns.

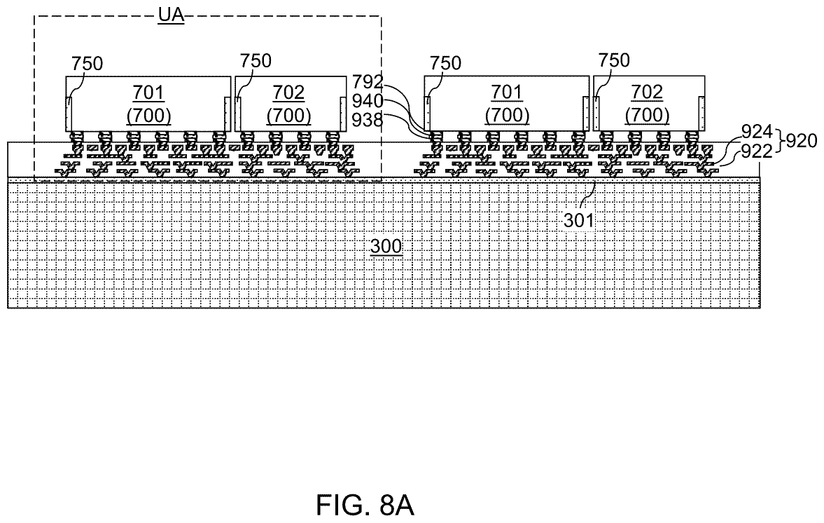

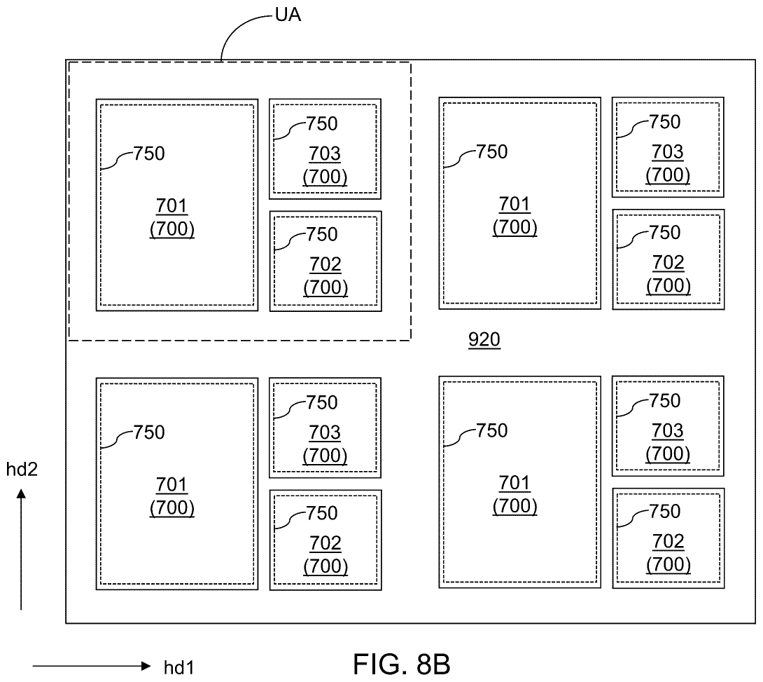

Referring to FIGS. 8A and 8B, a set of at least one elastically padded semiconductor die (700, 750) may be bonded to each interposer 920. Each of the at least one elastically padded semiconductor die (700, 750) may independently be any of the elastically padded semiconductor dies (700, 750) described with reference to FIGS. 5A-5C, 5D, or 5E-5G. In one embodiment, the interposers 920 may be arranged as a two-dimensional periodic array, and multiple sets of at least one elastically padded semiconductor die (700, 750) may be bonded to the interposers 920 as a two-dimensional periodic rectangular array of sets of the at least one elastically padded semiconductor die (700, 750). In one embodiment, each set of at least one elastically padded semiconductor die (700, 750) may comprise a plurality of elastically padded semiconductor dies (700, 750). For example, each set of at least one elastically padded semiconductor die (700, 750) may comprise a first elastically padded semiconductor die (701, 750), a second elastically padded semiconductor die (702, 750), a third elastically padded semiconductor die (703, 750), etc. The first elastically padded semiconductor die (701, 750) is a combination of a first semiconductor die 701 and an elastic protective material portion 750 therearound; the second elastically padded semiconductor die (702, 750) is a combination of a second semiconductor die 702 and an elastic protective material portion 750 therearound; and the third elastically padded semiconductor die (703, 750) is a combination of a third semiconductor die 703 and an elastic protective material portion 750 therearound; etc.

In one embodiment, one or more of the elastically padded semiconductor dies (700, 750) may include at least one elastically padded logic die that includes a logic die (such as an elastically padded system-on-chip (SoC) die) and an elastic protective material portion 750 therearound. Further, one or more of the semiconductor dies that are bonded to each interposer 920 may not have an elastic protective material portion therearound. In one embodiment, one or more of the semiconductor dies that are bonded to each interposer 920 may include a high bandwidth memory (HBM) die including a vertical stack of static random access memory (SRAM) dies that are interconnected to one another through microbumps and are laterally surrounded by an epoxy molding material enclosure frame.

Each elastically padded semiconductor die (700, 750) may comprise a respective array of metal bump structures 792. Each of the elastically padded semiconductor dies (700, 750) may be positioned in a face-down position such that metal bump structures 792 face a respective subset of the first solder material portions 940. Each set of at least one elastically padded semiconductor die (700, 750) may be placed within a respective unit area UA. Placement of the elastically padded semiconductor dies (700, 750) may be performed using a pick and place apparatus such that each of the metal bump structures 792 is positioned over a respective one of the first solder material portions 940.

Thus, an interposer 920 including interposer-side bonding structures 938 thereupon may be provided, and at least one elastically padded semiconductor die (700, 750) including a respective set of metal bump structures 792 may be provided. The at least one elastically padded semiconductor die (700, 750) may be bonded to the interposer 920 using first solder material portions 940 that are bonded to a respective interposer-side bonding structure 938 and to a respective one of the metal bump structures 792. Each set of at least one elastically padded semiconductor die (700, 750) may be attached to a respective interposer 920 through a respective set of first solder material portions 940. Generally speaking, a singulated semiconductor die (700, 750) comprising an elastically padded semiconductor die (700, 750) may be bonded to a packaging structure (such as an interposer 920) using an array of first solder material portions 940.

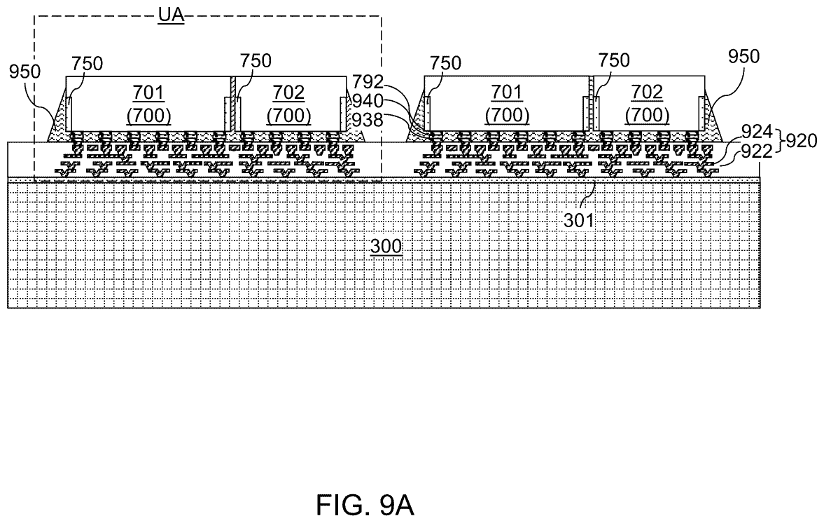

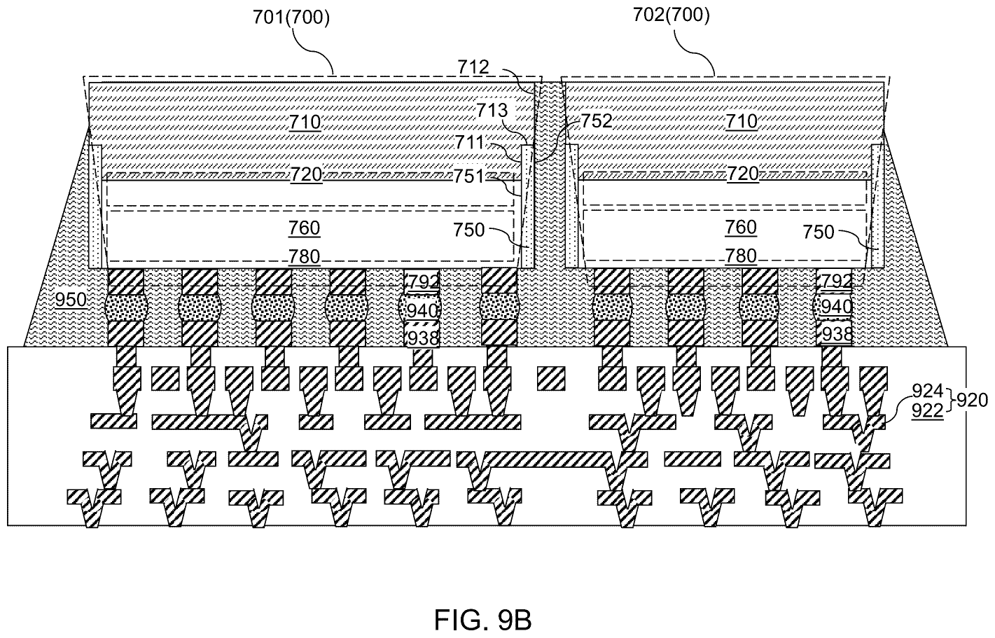

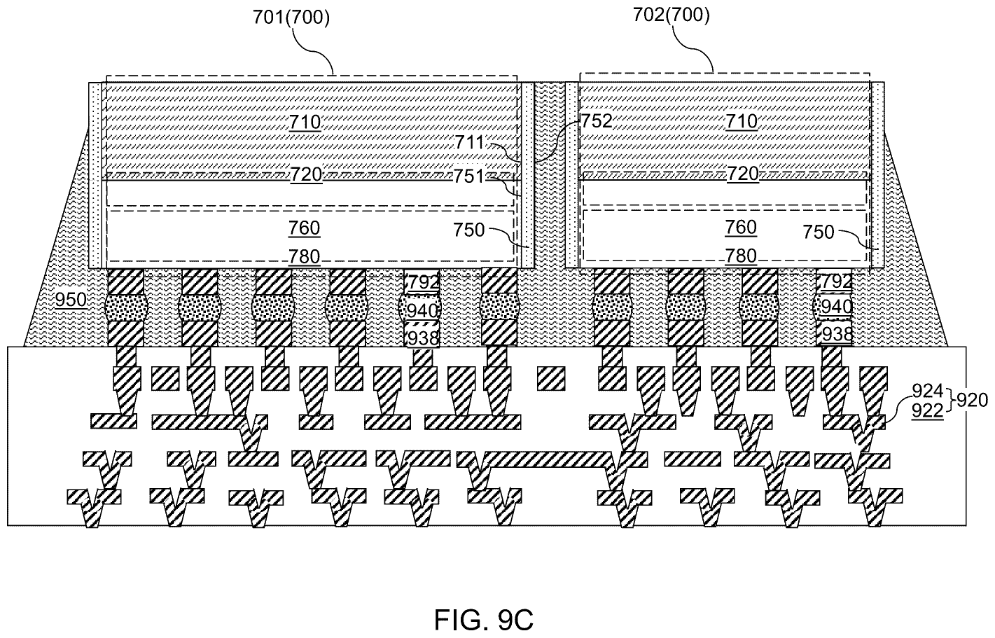

Referring to FIGS. 9A, 9B, and 9C, an underfill material may be applied into each gap between the interposers 920 and sets of at least one elastically padded semiconductor die (700, 750) that are bonded to the interposers 920. An underfill material portion 950 may be formed within each unit area UA between an interposer 920 and an overlying set of at least one elastically padded semiconductor die (700, 750). The underfill material portions 950 may be formed by injecting the underfill material around a respective array of first solder material portions 940 in a respective unit area UA. Any known underfill material application method may be used, which may be, for example, the capillary underfill method, the molded underfill method, or the printed underfill method.

Within each unit area UA, an underfill material portion 950 may laterally surround, and contact, each of the first solder material portions 940 within the unit area UA. The underfill material portion 950 may be formed around, and contact, the first solder material portions 940, the interposer-side bonding structures 938, and the metal bump structures 792 in the unit area UA. Each interposer 920 in a unit area UA comprises interposer-side bonding structures 938. At least one elastically padded semiconductor die (700, 750) comprising a respective set of metal bump structures 792 is attached to the interposer-side bonding structures 938 through a respective set of first solder material portions 940 within each unit area UA. Within each unit area UA, an underfill material portion 950 laterally surrounds the interposer-side bonding structures 938 and the metal bump structures 792 of the at least one elastically padded semiconductor die (700, 750).

According to an aspect of the present disclosure, the underfill material in the underfill material portion 950 has a second Young's modulus that is lower than the first Young's modulus. Thus, one, and/or each, of the elastic protective material portions 750 may have a first Young's modulus, and the underfill material portion 950 has a second Young's modulus that is less than the first Young's modulus. In one embodiment, the first Young's modulus is in a range from 10 GPa to 90 GPa, and the second Young's modulus is in a range from 3 GPa to 10 GPa. The fill material composition and the cross-linking of the polymer material within the underfill material portion 950 are controlled such that the second Young's modulus is less than the first Young's modulus. This arrangement induces primary deformation of the bonded assembly within the underfill material portion 950 while allowing auxiliary deformation of the bonded assembly within the elastic protective material portions 750. Thus, the auxiliary deformation of the elastic protective material portions 750 reduces the mechanical stress that needs to be absorbed by the underfill material portion 950, and reduces delamination and cracking of the underfill material portion 950 within each bonded assembly.

In embodiments in which the elastic protective material portions 750 comprise a stiff underfill material, the underfill material of the underfill material portion 950 has a lower Young's modulus so that the underfill material portion 950 functions as a primary stress absorber structure. In this embodiment, the elastic protective material portions 750 may comprise a first underfill material having a Young's modulus greater than 10 GPa, and the underfill material portion 950 comprises a second underfill material having a different material composition than the first underfill material and having a Young's modulus in a range from 3 GPa to 10 GPa.

Generally, the semiconductor dies 700 comprise metal bump structures 792, and the packaging structure (such as an interposer 920) to which the semiconductor dies 700 are bonded comprises additional metal bump structures (such as interposer-side bonding structures 938). The first solder material portions 940 are bonded to the metal bump structures 792 and the additional metal bump structures (such as the interposer-side bonding structures 938). The underfill material portion 950 laterally surrounds the first solder material portions 940. In one embodiment, the underfill material portion 950 contacts the entirety of outer sidewalls 752 of the elastic protective material portion 750 and contacts segments of sidewalls of at least one semiconductor die substrate 710 as illustrated in FIG. 9B. In one embodiment, the entirety of outer sidewalls of the dielectric material layers 760 that are in contact with the elastic protective material portion 750 is located within vertical planes containing a set of sidewalls of the semiconductor die substrate 710 as illustrated in FIG. 9C.

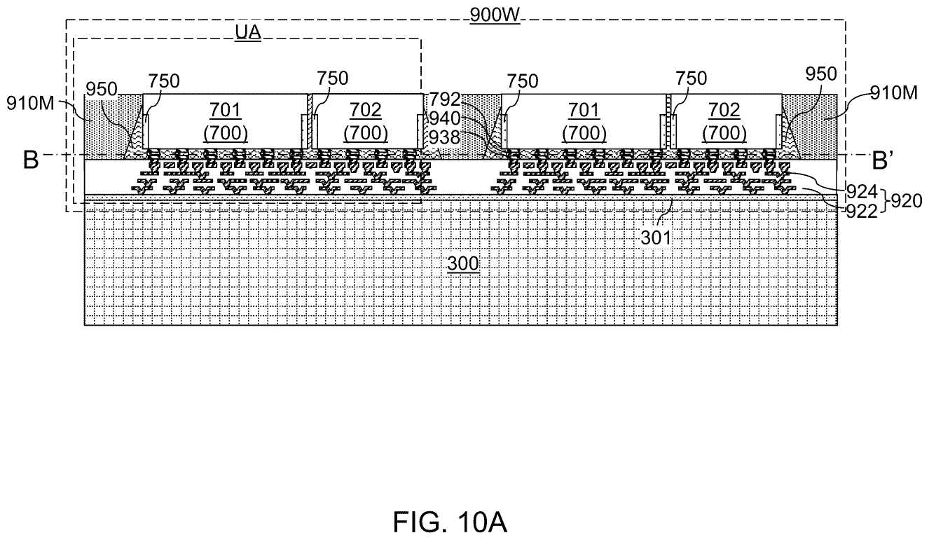

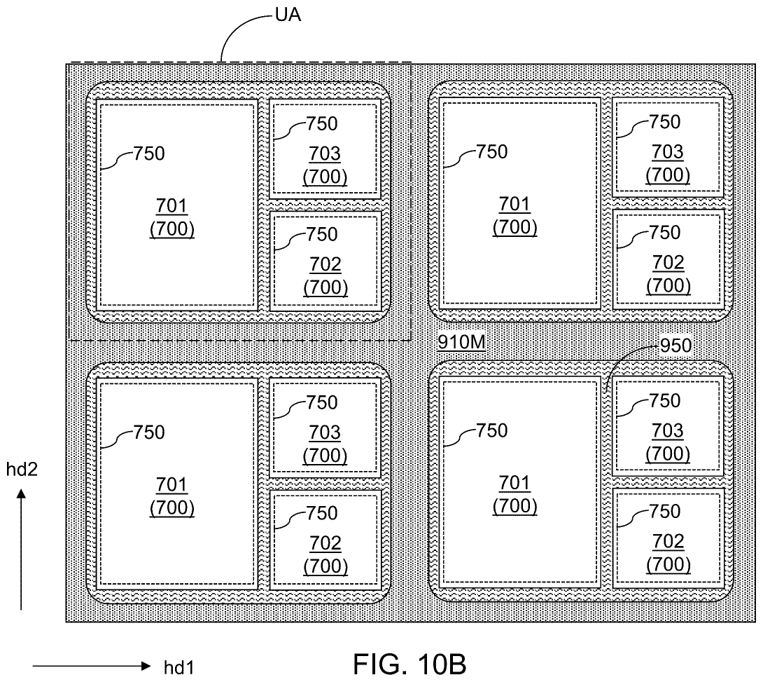

Referring to FIGS. 10A and 10B, an epoxy molding compound (EMC) may be applied to the gaps between contiguous assemblies of a respective set of elastically padded semiconductor dies (700, 750) and a respective underfill material portion 950.

The EMC may include an epoxy-containing compound that may be hardened (i.e., cured) to provide a dielectric material portion having sufficient stiffness and mechanical strength. The EMC may include epoxy resin, hardener, silica (as a filler material), and other additives. The EMC may be provided in a liquid form or in a solid form depending on the viscosity and flowability. Liquid EMC provides better handling, good flowability, less voids, better fill, and less flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks, and may enhance flowability. The curing temperature of the EMC may be lower than the release (debonding) temperature of the first adhesive layer 301 in embodiments in which the adhesive layer includes a thermally debonding material. For example, the curing temperature of the EMC may be in a range from 125° C. to 150° C.

The EMC may be cured at a curing temperature to form an EMC matrix 910M that laterally surrounds and embeds each assembly of a set of elastically padded semiconductor dies (700, 750) and an underfill material portion 950. The EMC matrix 910M includes a plurality of epoxy molding compound (EMC) die frames that may be laterally adjoined to one another. Each EMC die frame is a portion of the EMC matrix 910M that is located within a respective unit area UA. Thus, each EMC die frame laterally surrounds and embeds a respective set of elastically padded semiconductor dies (700, 750) and a respective underfill material portion 950. Young's modulus of pure epoxy is about 3.35 GPa, and Young's modulus of the EMC may be higher than Young's modulus of pure epoxy by adding additives. Young's modulus of EMC may be in a range from 15 GPa to 25 GPa. In one embodiment, the EMC may have Young's modulus that is less than the first Young's modulus and is greater than the second Young's modulus. In another embodiment, the EMC may have Young's modulus that is greater than the first Young's modulus and is greater than the second Young's modulus.

Portions of the EMC matrix 910M that overlies the horizontal plane including the top surfaces of the elastically padded semiconductor dies (700, 750) may be removed by a planarization process. For example, the portions of the EMC matrix 910M that overlies the horizontal plane may be removed using a chemical mechanical planarization (CMP). The combination of the remaining portion of the EMC matrix 910M, the elastically padded semiconductor dies (700, 750), the underfill material portions 950, and the two-dimensional array of interposers 920 comprises a reconstituted wafer 900W. Each portion of the EMC matrix 910M located within a unit area UA constitutes an EMC die frame.

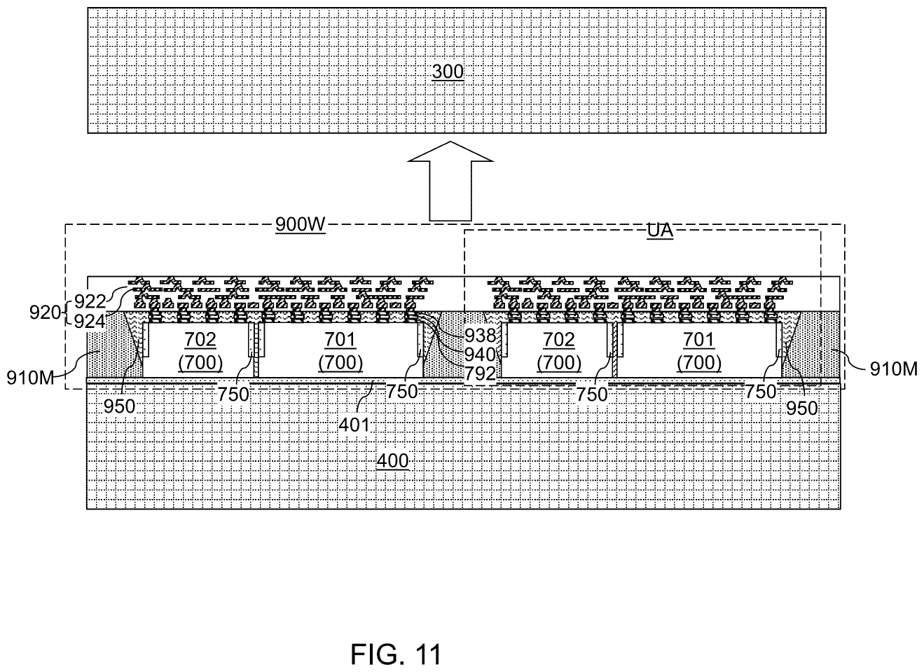

Referring to FIG. 11, a second adhesive layer 401 may be applied to the physically exposed planar surface of the reconstituted wafer 900W, i.e., the physically exposed surfaces of the EMC matrix 910M, the elastically padded semiconductor dies (700, 750), and the underfill material portions 950. In one embodiment, the second adhesive layer 401 may comprise a same material as, or may comprise a different material from, the material of the first adhesive layer 301. In embodiments in which the first adhesive layer 301 comprises a thermally decomposing adhesive material, the second adhesive layer 401 may comprise another thermally decomposing adhesive material that decomposes at a higher temperature, or may comprise a light-to-heat conversion material.

A second carrier wafer 400 may be attached to the second adhesive layer 401. The second carrier wafer 400 may be attached to the opposite side of the reconstituted wafer 900W relative to the first carrier wafer 300. Generally, the second carrier wafer 400 may comprise any material that may be used for the first carrier wafer 300. The thickness of the second carrier wafer 400 may be in a range from 500 microns to 2,000 microns, although lesser and greater thicknesses may also be used.

The first adhesive layer 301 may be decomposed by ultraviolet radiation or by a thermal anneal at a debonding temperature. In embodiments in which the first carrier wafer 300 includes an optically transparent material and the first adhesive layer 301 includes an LTHC layer, the first adhesive layer 301 may be decomposed by irradiating ultraviolet light through the transparent carrier wafer. The LTHC layer may absorb the ultraviolet radiation and generate heat, which decomposes the material of the LTHC layer and cause the transparent first carrier wafer 300 to be detached from the reconstituted wafer 900W. In embodiments in which the first adhesive layer 301 includes a thermally decomposing adhesive material, a thermal anneal process at a debonding temperature may be performed to detach the first carrier wafer 300 from the reconstituted wafer 900W.

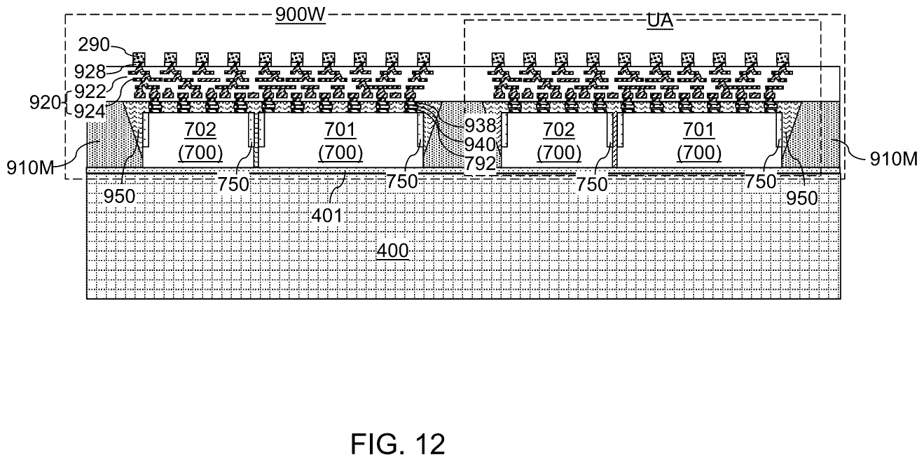

Referring to FIG. 12, interposer bonding pads 928 and second solder material portions 290 may be formed by depositing and patterning a stack of at least one metallic material that may function as metallic bumps and a solder material layer. The metallic fill material for the interposer bonding pads 928 may include copper. Other suitable materials are within the contemplated scope of disclosure. The thickness of the interposer bonding pads 928 may be in a range from 5 microns to 100 microns, although lesser or greater thicknesses may also be used. The interposer bonding pads 928 and the second solder material portions 290 may have horizontal cross-sectional shapes of rectangles, rounded rectangles, or circles. Other suitable shapes are within the contemplated scope of disclosure. In embodiments in which the interposer bonding pads 928 are formed as C4 (controlled collapse chip connection) pads, the thickness of the interposer bonding pads 928 may be in a range from 5 microns to 50 microns, although lesser or greater thicknesses may also be used. In some embodiments, the interposer bonding pads 928 may be, or include, underbump metallization (UBM) structures. The configurations of the interposer bonding pads 928 are not limited to be fan-out structures. Alternatively, the interposer bonding pads 928 may be configured for microbump bonding (i.e., C2 bonding), and may have a thickness in a range from 30 microns to 100 microns, although lesser or greater thicknesses may also be used. In such an embodiment, the interposer bonding pads 928 may be formed as an array of microbumps (such as copper pillars) having a lateral dimension in a range from 10 microns to 25 microns, and having a pitch in a range from 20 microns to 50 microns.

The interposer bonding pads 928 and the second solder material portions 290 may be formed on the opposite side of the EMC matrix 910M and the two-dimensional array of sets of elastically padded semiconductor dies (700, 750) relative to the interposer layer. The interposer layer includes a three-dimensional array of interposers 920. Each interposer 920 may be located within a respective unit area UA. Each interposer 920 may include redistribution dielectric layers 922, redistribution wiring interconnects 924 embedded in the redistribution dielectric layers 922, and interposer bonding pads 928. The interposer bonding pads 928 may be located on an opposite side of the interposer-side bonding structures 938 relative to the redistribution dielectric layers 922, and may be elastically connected to a respective one of the interposer-side bonding structures 938.

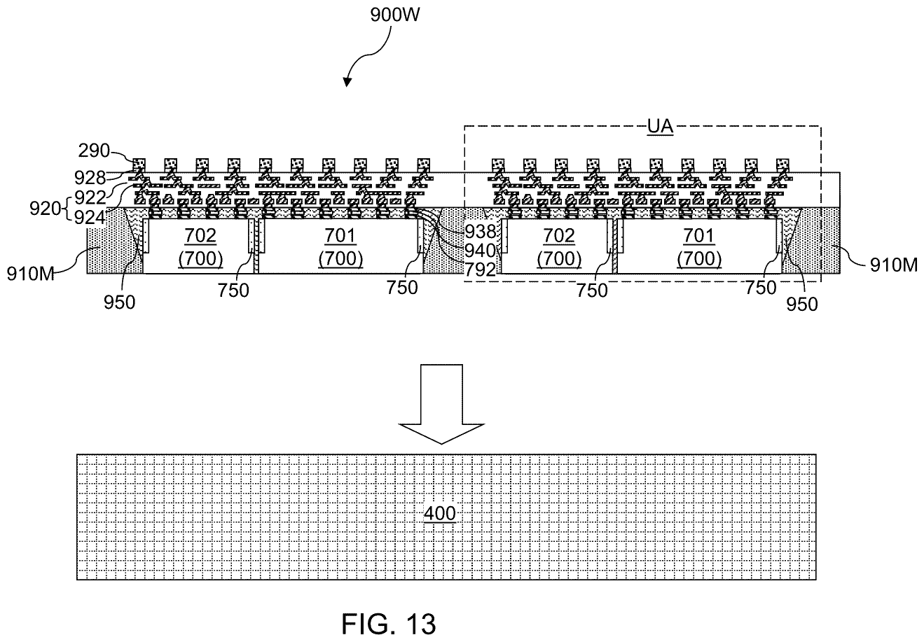

Referring to FIG. 13, the second adhesive layer 401 may be decomposed by ultraviolet radiation or by a thermal anneal at a debonding temperature. In embodiments in which the second carrier wafer 400 includes an optically transparent material and the second adhesive layer 401 includes an LTHC layer, the second adhesive layer 401 may be decomposed by irradiating ultraviolet light through the transparent carrier wafer. In embodiments in which the second adhesive layer 401 includes a thermally decomposing adhesive material, a thermal anneal process at a debonding temperature may be performed to detach the second carrier wafer 400 from the reconstituted wafer 900W.

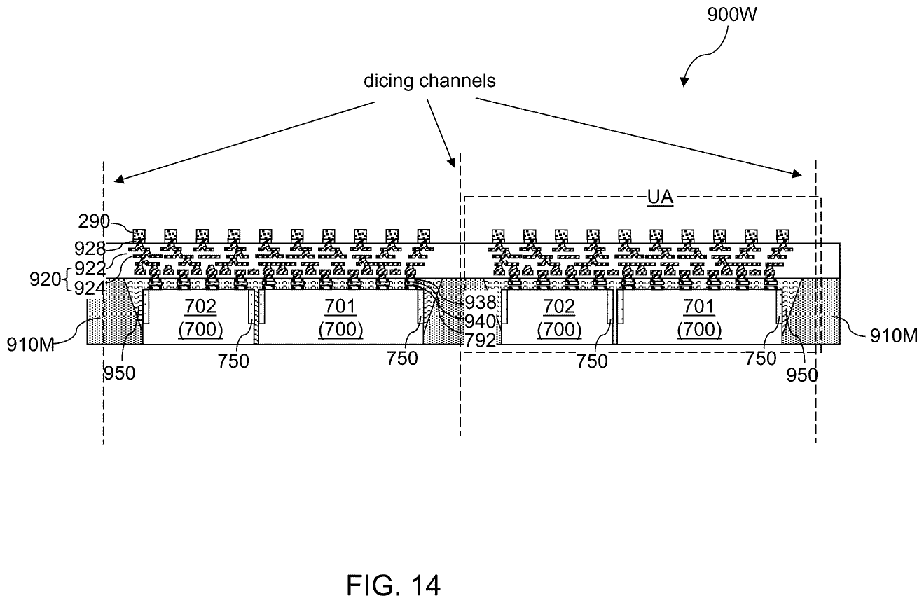

Referring to FIG. 14, the reconstituted wafer 900W including the interposer bonding pads 928 may be subsequently diced along dicing channels by performing a dicing process. The dicing channels correspond to the boundaries between neighboring pairs of die areas DA. Each diced unit from the reconstituted wafer 900W may include a fan-out package 900. In other words, each diced portion of the assembly of the two-dimensional array of sets of elastically padded semiconductor dies (700, 750), the two-dimensional array of underfill material portions 950, the EMC matrix 910M, and the two-dimensional array of interposers 920 constitutes a fan-out package 900. Each diced portion of the EMC matrix 910M constitutes a molding compound die frame 910. Each diced portion of the interposer layer (which includes the two-dimensional array of interposers 920) constitutes an interposer 920.

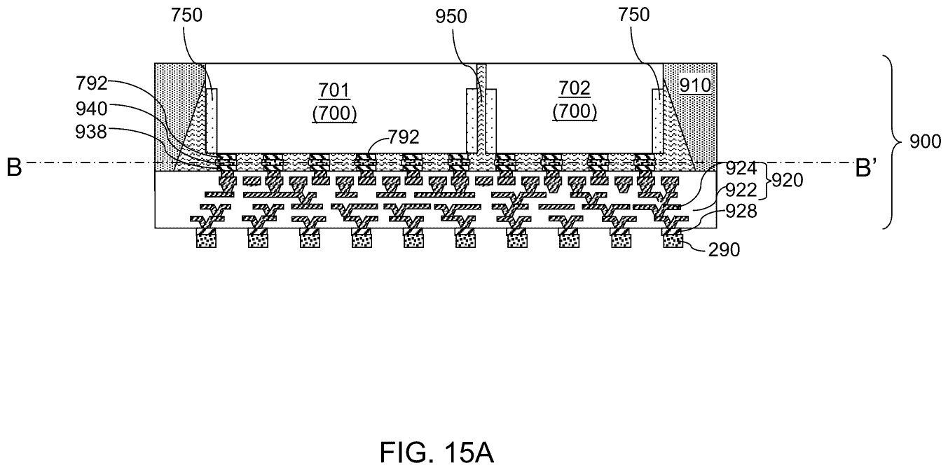

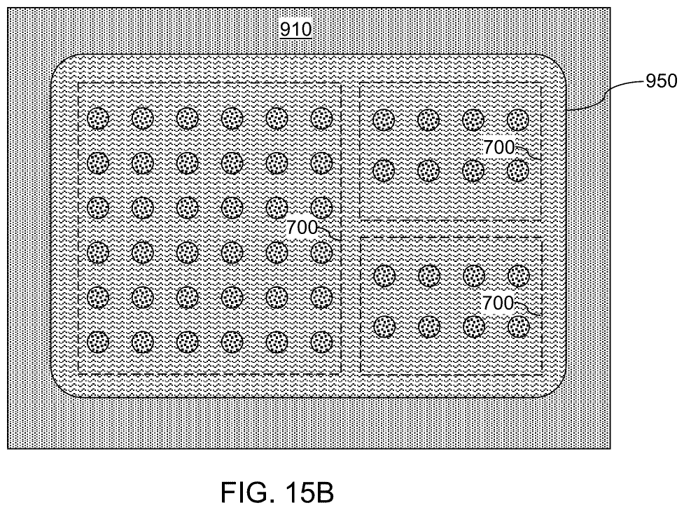

Referring to FIGS. 15A and 15B, a fan-out package 900 obtained by dicing the first exemplary structure at the processing steps of FIG. 14 is illustrated. The fan-out package 900 comprises an interposer 920 including interposer-side bonding structures 938, at least one elastically padded semiconductor die (700, 750) comprising a respective set of metal bump structures 792 that is attached to the interposer-side bonding structures 938 through a respective set of first solder material portions 940, an underfill material portion 950 laterally surrounding the interposer-side bonding structures 938 and the metal bump structures 792 of the at least one elastically padded semiconductor die (700, 750).

The fan-out package 900 may comprise a molding compound die frame 910 laterally surrounding the at least one elastically padded semiconductor die (700, 750) and comprising a molding compound material. In one embodiment, the molding compound die frame 910 may include sidewalls that are vertically coincident with sidewalls of the interposer 920, i.e., located within same vertical planes as the sidewalls of the interposer 920. Generally, the molding compound die frame 910 may be formed around the at least one elastically padded semiconductor die (700, 750) after formation of the underfill material portion 950 within each fan-out package 900. The molding compound material contacts a peripheral portion of a planar surface of the interposer 920.

Generally an assembly including at least one elastically padded semiconductor die (700, 750) and an interposer 920 is provided. The assembly may be in a form of a package, i.e., a semiconductor package. In one embodiment, the assembly may comprise a fan-out package including at least one elastically padded semiconductor die (700, 750), an interposer 920 attached to the at least one elastically padded semiconductor die (700, 750), and an underfill material portion 950 located between the at least one elastically padded semiconductor die (700, 750) and the interposer 920.

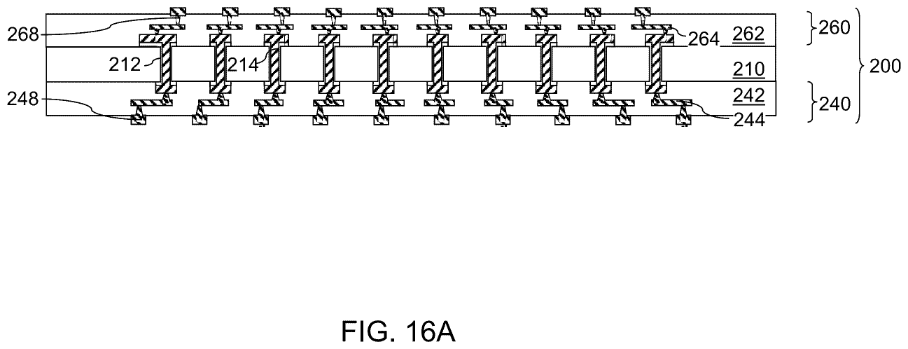

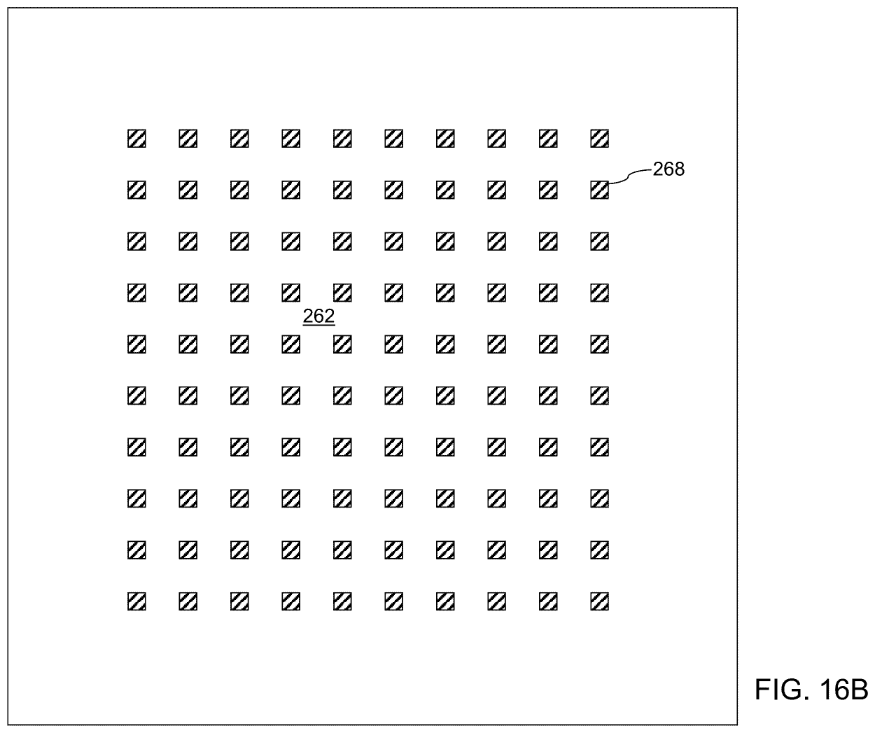

Referring to FIGS. 16A and 16B, a packaging substrate 200 is provided. The packaging substrate 200 may be a cored packaging substrate including a core substrate 210, or a coreless packaging substrate that does not include a package core. Alternatively, the packaging substrate 200 may include a system-on-integrated packaging substrate (SoIS) including redistribution layers and/or dielectric interlayers, at least one embedded interposer (such as a silicon interposer). Such a system-integrated packaging substrate may include layer-to-layer interconnections using solder material portions, microbumps, underfill material portions (such as molded underfill material portions), and/or an adhesion film. While the present disclosure is described using an exemplary substrate package, it is understood that the scope of the present disclosure is not limited by any particular type of substrate package and may include an SoIS. The core substrate 210 may include a glass epoxy plate including an array of through-plate holes. An array of through-core via structures 214 including a metallic material may be provided in the through-plate holes. Each through-core via structure 214 may, or may not, include a cylindrical hollow therein. Optionally, dielectric liners 212 may be used to elastically isolate the through-core via structures 214 from the core substrate 210.

The packaging substrate 200 may include board-side surface laminar circuit (SLC) 240 and a chip-side surface laminar circuit (SLC) 260. The board-side SLC may include board-side insulating layers 242 embedding board-side wiring interconnects 244. The chip-side SLC 260 may include chip-side insulating layers 262 embedding chip-side wiring interconnects 264. The board-side insulating layers 242 and the chip-side insulating layers 262 may include a photosensitive epoxy material that may be lithographically patterned and subsequently cured. The board-side wiring interconnects 244 and the chip-side wiring interconnects 264 may include copper that may be deposited by electroplating within patterns in the board-side insulating layers 242 or the chip-side insulating layers 262.

In one embodiment, the packaging substrate 200 includes a chip-side surface laminar circuit 260 comprising chip-side wiring interconnects 264 connected to an array of substrate bonding pads 268 that may be bonded to the array of second solder material portions 290, and a board-side surface laminar circuit 240 including board-side wiring interconnects 244 connected to an array of board-side bonding pads 248. The array of board-side bonding pads 248 is configured to allow bonding through solder balls. The array of substrate bonding pads 268 may be configured to allow bonding through C4 solder balls. Generally, any type of packaging substrate 200 may be used. While the present disclosure is described using an embodiment in which the packaging substrate 200 includes a chip-side surface laminar circuit 260 and a board-side surface laminar circuit 240, embodiments are expressly contemplated herein in which one of the chip-side surface laminar circuit 260 and the board-side surface laminar circuit 240 is omitted, or is replaced with an array of bonding structures such as microbumps. In an illustrative example, the chip-side surface laminar circuit 260 may be replaced with an array of microbumps or any other array of bonding structures.

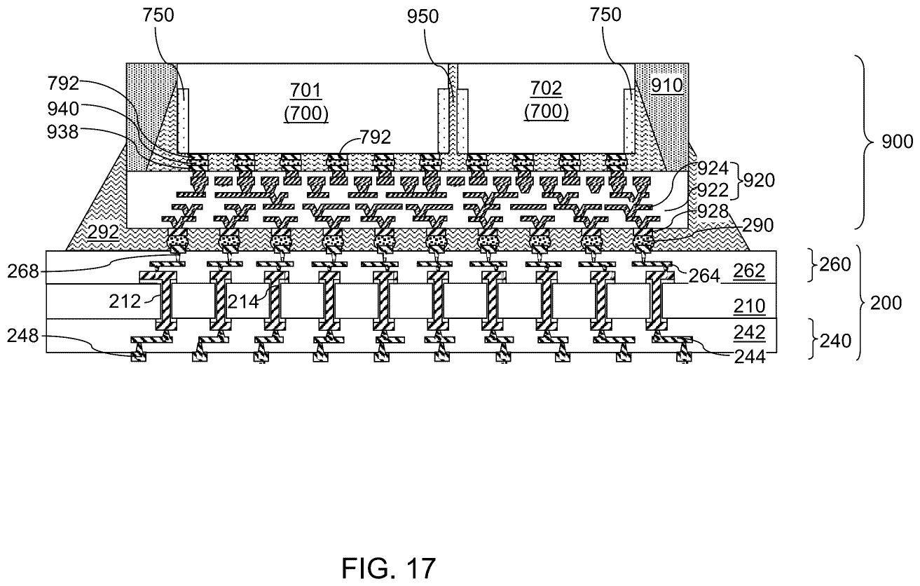

Referring to FIG. 17, the fan-out package 900 may be disposed over the packaging substrate 200 with an array of the second solder material portions 290 therebetween. In embodiments in which the second solder material portions 290 are formed on the interposer bonding pads 928 of the fan-out package 900, the second solder material portions 290 may be disposed on the substrate bonding pads 268 of the packaging substrate 200. A reflow process may be performed to reflow the second solder material portions 290, thereby inducing bonding between the fan-out package 900 and the packaging substrate 200. Each second solder material portion 290 may be bonded to a respective one of the interposer bonding pads 928 and to a respective one of the substrate bonding pads 268. In one embodiment, the second solder material portions 290 may include C4 solder balls, and the fan-out package 900 may be attached to the packaging substrate 200 through an array of C4 solder balls. Generally, the fan-out package 900 may be bonded to the packaging substrate 200 such that the interposer 920 is bonded to the packaging substrate 200 by an array of solder material portions (such as the second solder material portions 290).

An underfill material is applied to the gap between the fan-out package 900 and the packaging substrate 200 to form an underfill material portion, which is herein referred to as an interposer-substrate underfill material portion 292.

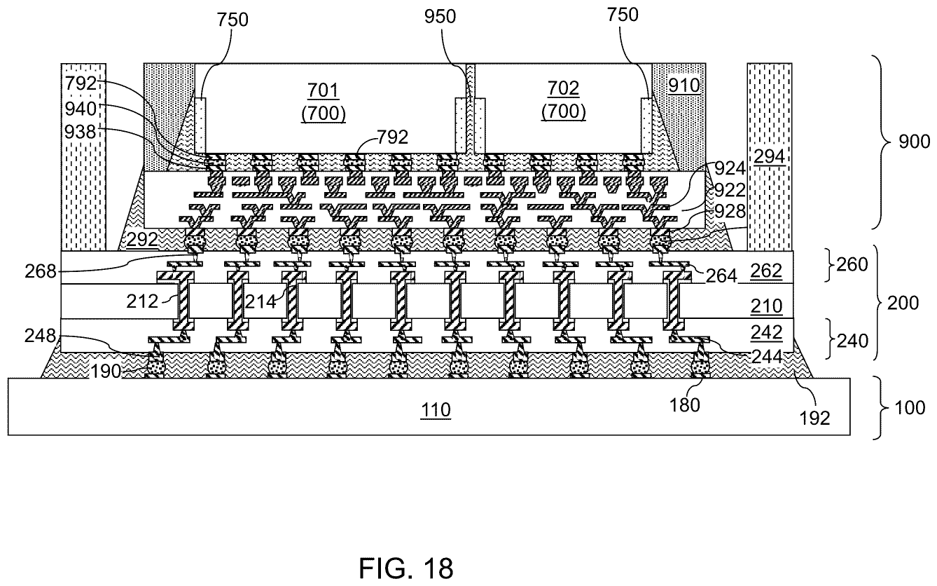

Referring to FIG. 18, a stabilization structure 294 such as a stiffener ring may be attached to the packaging substrate 200. A printed circuit board (PCB) 100 including a PCB substrate 110 and PCB bonding pads 180 may be provided. The PCB 100 includes a printed circuitry (not shown) at least on one side of the PCB substrate 110. An array of solder joints 190 may be formed to bond the array of board-side bonding pads 248 to the array of PCB bonding pads 180. The solder joints 190 may be formed by disposing an array of solder balls between the array of board-side bonding pads 248 and the array of PCB bonding pads 180, and by reflowing the array of solder balls. An underfill material portion 192 may be formed around the solder joints 190 by applying and shaping an underfill material. The packaging substrate 200 is attached to the PCB 100 through the array of solder joints 190.

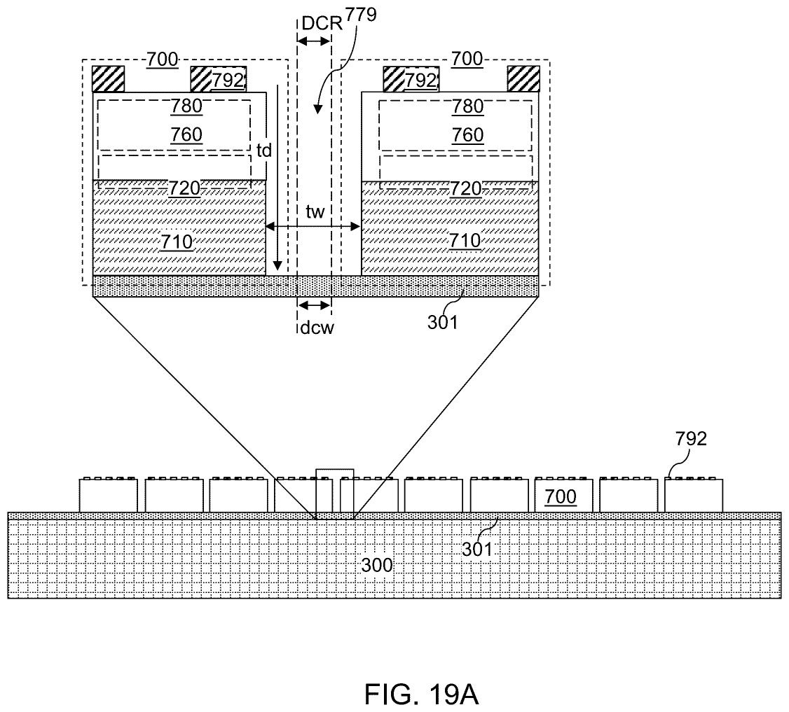

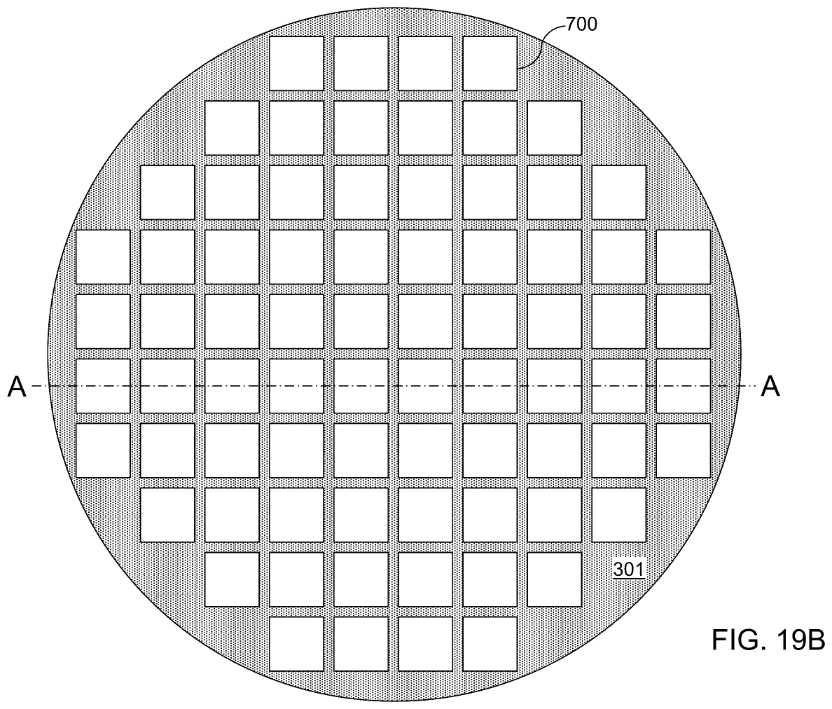

Referring to FIGS. 19A and 19B, a second exemplary structure according to a second embodiment of the present disclosure is illustrated. The second exemplary structure includes a two-dimensional array of semiconductor dies 700 disposed on a carrier wafer 300. The carrier wafer 300 may comprise any material that may provide sufficient mechanical support to the two-dimensional array of semiconductor dies 700, and to a reconstituted wafer to be subsequently formed therefrom. The carrier wafer 300 may comprise a dielectric substrate, a semiconductor substrate, or a conductive substrate. In one embodiment, the carrier wafer 300 may comprise a glass substrate or a commercially available semiconductor wafer. A die attachment film 301 may be formed on the top surface of the carrier wafer 300, and the two-dimensional array of semiconductor dies 700 may be attached to the top surface of the die attachment film 301. The two-dimensional array of semiconductor dies 700 may be arranged such that gaps having a uniform width are formed between neighboring pairs of semiconductor dies 700. Each of the gaps laterally extend along a respective horizontal direction as a trench 779 having a respective uniform width.

A rectangular grid of trenches 779 may be formed among the semiconductor dies 700 over the carrier wafer 300. Each neighboring pair of semiconductor dies 700 may be laterally spaced apart from each other by a uniform lateral spacing, which is the same as the trench width tw of the trenches 779. The trench width tw is greater than the width of dicing channel regions DCR, which are regions from which material are removed during a subsequent dicing process. The dicing channel regions DCR may comprise first dicing channel regions that laterally extend along the first horizontal direction with a dicing channel width dew along the second horizontal direction, and second dicing channel regions that laterally extend along the second horizontal direction with the dicing channel width dew along the first horizontal direction. The dicing channel width dew may be in a range from 30 microns to 150 microns, such as from 50 microns to 120 microns, although lesser and greater uniform widths may also be used.

A grid-shaped top surface segment of the die attachment film 301 is physically exposed underneath the rectangular grid of trenches 779. The trenches are interconnected among one another to provide the rectangular grid of interconnected and intersecting trenches 779. The rectangular grid of trenches 779 has a uniform depth is about the height (i.e., the thickness) of each semiconductor die 700. The depth of the rectangular grid of trenches 779 is herein referred to as a trench depth td. The trench depth td is the vertical distance between the horizontal plane including the topmost surface of the dielectric material layers 760 and the top surface of the die attachment film 301 that underlies the rectangular grid of trenches 779. In an illustrative example, the thickness of each semiconductor die 700 may be in a range from 5 microns to 600 microns, such as from 30 microns to 200 microns, although lesser and greater thicknesses may also be used.

Each trench 779 has a trench width tw that is greater than the dicing channel width dcw. The difference between the trench width tw and the dicing channel width dew determines the lateral width of elastic dielectric frames to be subsequently formed around each semiconductor die 700. Specifically, the lateral width (i.e., the lateral distance between a neighboring pair of an inner sidewall and an outer sidewall) of each elastic dielectric frame to be subsequently formed is about one half of the difference between the trench width tw and the dicing channel width dew. The lateral width of the elastic dielectric frames may be in a range from 1 micron to 300 microns, although lesser and greater lateral widths may also be used. Correspondingly, the trench width tw may be greater than the dicing channel width dew by a width differential in a range from 2 microns to 600 microns.

Generally, a structure including a two-dimensional array of semiconductor dies 700 and a rectangular grid of trenches 779 that laterally extend along dicing channel regions DCR may be provided. The trenches 779 are wider than the width of each of the dicing channel regions DCR. In the second exemplary structure, the structure comprises a carrier wafer 300; the two-dimensional array of semiconductor dies 700 is attached to a top surface of the carrier wafer 300 through a die attachment film 301; and the rectangular grid of trenches 779 comprises lateral gaps between neighboring pairs of semiconductor dies 700 within the two-dimensional array of semiconductor dies 700.

Each semiconductor die 700 may comprise semiconductor devices 720 located on a semiconductor die substrate 710, metal interconnect structures 780 embedded within dielectric material layers 760 and electrically connected to the metal interconnect structures 780, and metal bump structures 792 located on a topmost dielectric material layer among the dielectric material layers 760. As discussed above, the semiconductor devices 720 may comprise field effect transistors, diodes, capacitors, resistors, radio-frequency switching devices, memory cells, photonic devices, and/or any other type of semiconductor devices known in the art. The dielectric material layers 760 may comprise, and/or may consist of, inorganic dielectric materials such as silicate glasses, silicon nitride, silicon carbide nitride, silicon oxynitride, dielectric metal oxides, etc. It is noted that organosilicate glass is primarily composed of inorganic silicon-oxygen bonds, and thus, despite presence of some C—H bonds, organosilicate glass is an inorganic material despite its name. In one embodiment, the dielectric material layers 760 may be free of polymer materials. Alternatively, a polymer layer (such as a polyimide layer) may be used at the topmost level of the dielectric material layers 760. The metal interconnect structures 780 may comprise metal line structures, metal pad structures, and/or metal via structures. The metal interconnect structures 780 may comprise tungsten, copper, and/or aluminum. Each semiconductor die 700 may comprise a two-dimensional array of metal bump structures 792, which may be configured as microbump structures (such as copper pillars configured for chip connection bonding), or bonding pads (such as controlled-collapse chip connection (C4) bonding pads).

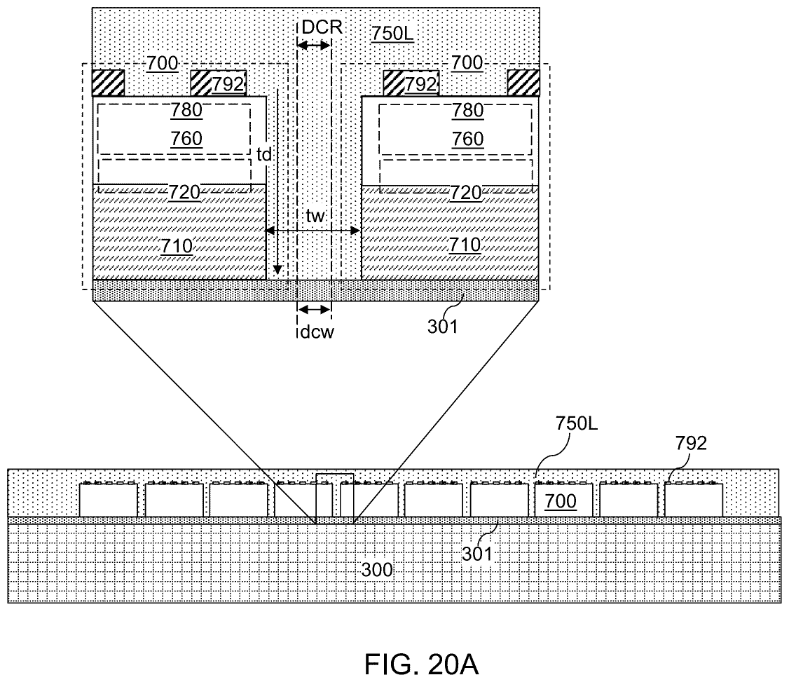

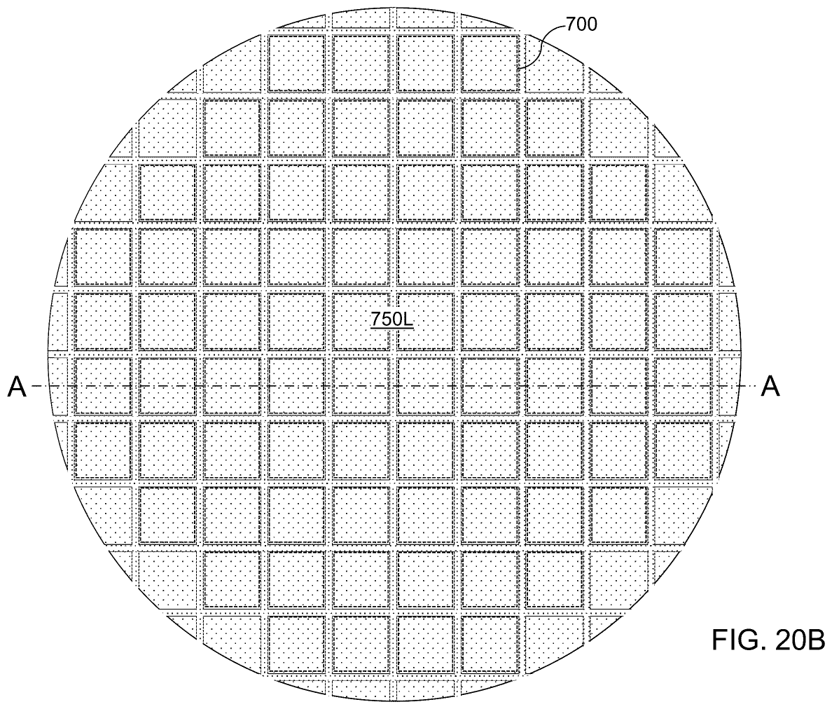

Referring to FIGS. 20A and 20B, the processing steps described with reference to FIGS. 3A and 3B may be performed to deposit an elastic dielectric fill material in the rectangular grid of trenches 779. The elastic dielectric fill material forms an elastic dielectric material layer 750L that fills the rectangular grid of trenches 779 and extends over the topmost surface of the dielectric material layers 760 and the metal bump structures 792. The thickness of a horizontally-extending portion of the elastic dielectric material layer 750L above the dielectric material layers 760 between neighboring pairs of metal bump structures 792 may be in a range from 50 microns to 500 microns, depending on the process used to form the elastic dielectric material layer 750L. The material composition and the material property of the elastic dielectric fill material may be the same as described above.

Generally, the rectangular grid of trenches 779 may be filled with the elastic dielectric fill material having the first Young's modulus. In the second exemplary structure, the elastic dielectric fill material may be deposited directly on the die attachment film 301 and on a set of sidewalls of the two-dimensional array of semiconductor dies 700.

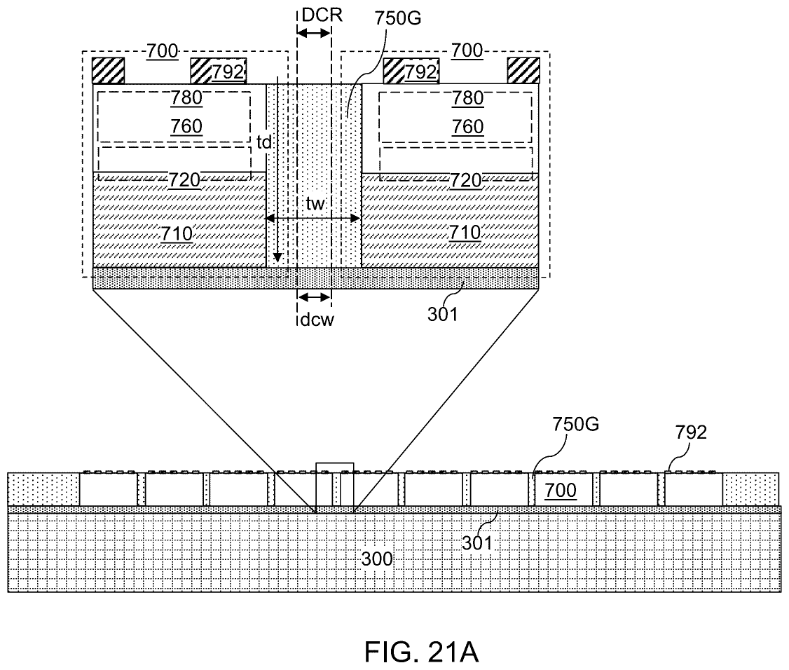

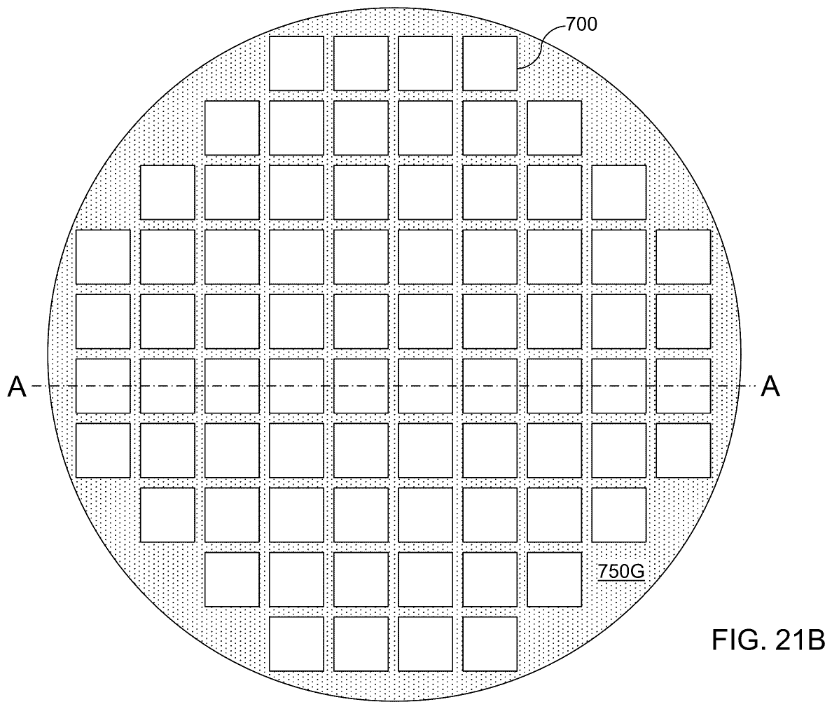

Referring to FIGS. 21A and 21B, the horizontally-extending portion of the elastic dielectric material layer 750L overlying the horizontal plane including the topmost surface of the dielectric material layers 760 may be removed. For example, an isotropic etch process, an anisotropic etch process, and/or a chemical mechanical polishing process may be performed to remove the horizontally-extending portion of the elastic dielectric material layer 750L from above the horizontal plane including the topmost surface of the dielectric material layers 760.

Generally, portions of the elastic dielectric fill material located outside the trenches 779 may be removed, while portions of the elastic dielectric fill material located inside the trenches 779 are not removed. The remaining portion of the elastic dielectric fill material in the trenches 779 comprise a grid network of elastic dielectric fill material rails, which is herein referred to as an elastic dielectric fill material grid 750G. The elastic dielectric fill material grid 750G has a uniform depth that is the same as, or is about the same as, the vertical distance between the horizontal plane including the topmost surface of the dielectric material layers 760 and the horizontal plane including the bottom surfaces of the semiconductor die substrates 710. The combination of the two-dimensional array of semiconductor dies 700 and the grid-shaped portion of the elastic dielectric fill material filling the rectangular grid of trenches 779 comprises a reconstituted wafer.

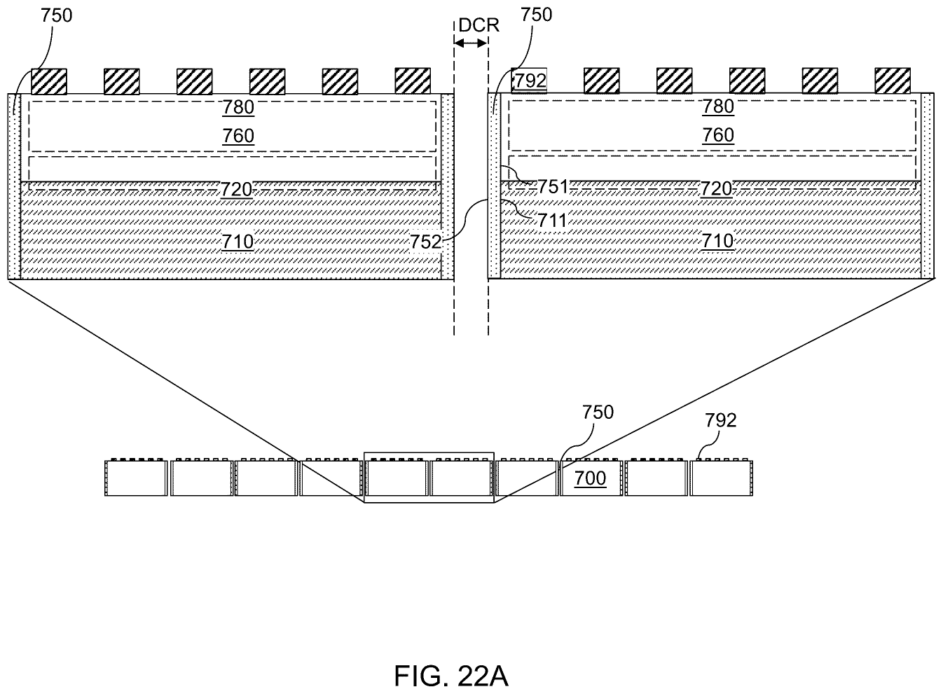

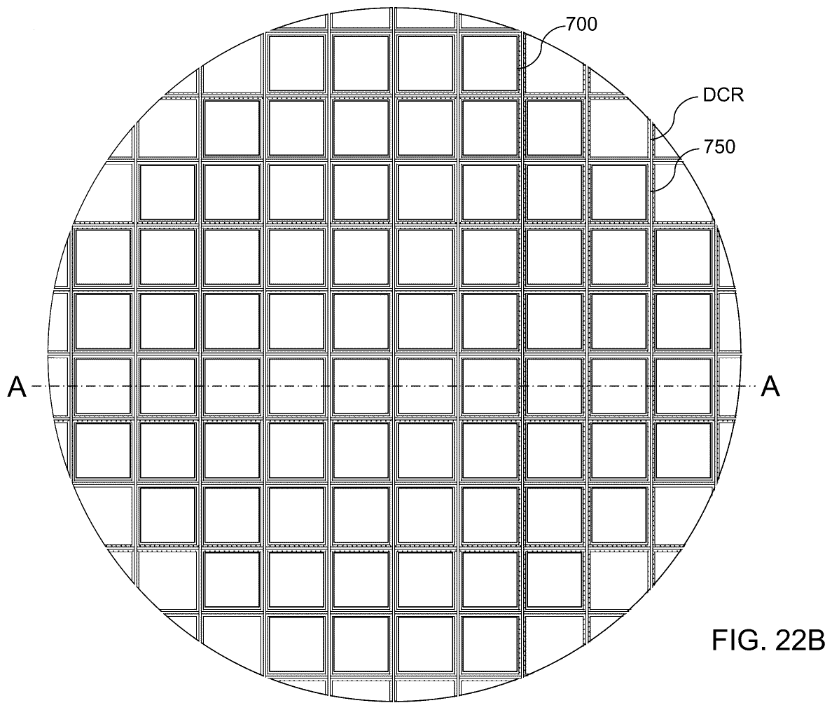

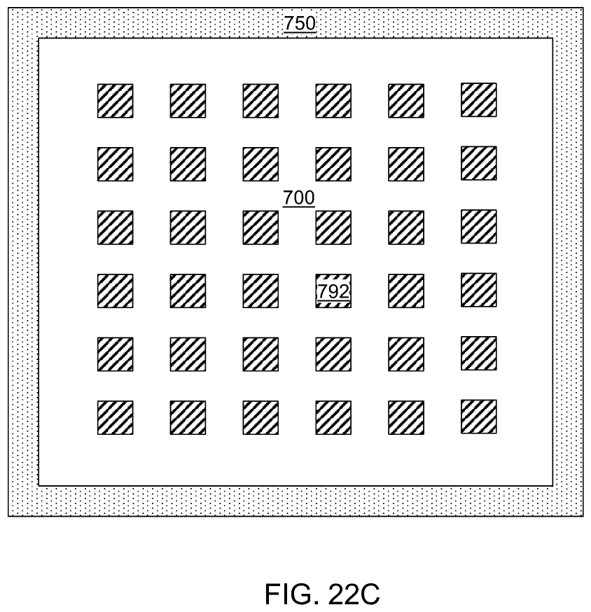

Referring to FIGS. 22A, 22B, and 22C, the carrier wafer 300 may be detached from the reconstituted wafer by decomposing the die attachment film 301. The reconstituted wafer may be subsequently diced into a plurality of singulated semiconductor dies (700, 750). Generally, the combination of the two-dimensional array of semiconductor dies 700 and a grid-shaped portion of the elastic dielectric fill material filling the rectangular grid of trenches 779 may be diced along the dicing channel regions DCR. The volume of the dicing channel regions DCR corresponds to the volume of materials that are removed during the dicing process. A plurality of singulated semiconductor dies (700, 750) is formed. Each singulated semiconductor die (700, 750) comprises a portion of the elastic dielectric fill material having a shape of a rectangular frame. As such, each singulated semiconductor die (700, 750) is an elastically padded semiconductor die (700, 750) comprising a combination of a semiconductor die 700 and an elastic protective material portion 750. Thus, a plurality of elastically padded semiconductor dies (700, 750) is formed

Each of the elastically padded semiconductor dies (700, 750) comprises a respective singulated semiconductor die (700, 750) that includes semiconductor devices 720 and metal bump structures 792 located on dielectric material layers 760, and further comprises an elastic protective material portion 750 comprising a portion of the elastic dielectric fill material and laterally surrounding the dielectric material layers 760. In one embodiment, each elastically padded semiconductor die (700, 750) comprises: a semiconductor die substrate 710; semiconductor devices 720 located on the semiconductor die substrate 710; metal interconnect structures 780 formed within dielectric material layers 760 and electrically connected to the metal interconnect structures 780; metal bump structures 792 located on a topmost dielectric material layer among the dielectric material layers 760; and an elastic protective material portion 750 comprising an elastic dielectric fill material and laterally surrounding the dielectric material layers 760 and the semiconductor die substrate 710.

In one embodiment, each semiconductor die substrate 710 in an elastically padded semiconductor die (700, 750) may comprise sidewalls 711 in contact with inner sidewalls 751 of the elastic protective material portion 750. In one embodiment, the entirety of outer sidewalls of the dielectric material layers 760 may be in contact with the elastic protective material portion 750 within each elastically padded semiconductor die (700, 750). The entirety of outer sidewalls of the dielectric material layers 760 may be located within vertical planes containing the sidewalls 711 of the semiconductor die substrate 710. In one embodiment, the entirety of sidewalls of the semiconductor die substrate 710 is in contact with the elastic protective material portion 750.

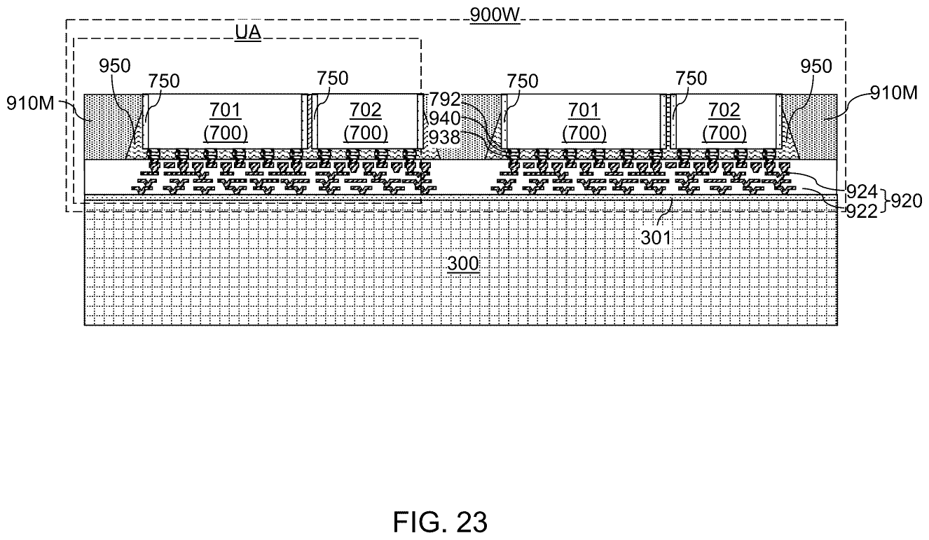

Referring to FIG. 23, the processing steps described with reference to FIGS. 6A-10B may be performed to form a reconstituted wafer 900W including an EMC matrix 910M. As described above, at least one singulated semiconductor die (700, 750) may be attached to a packaging structure (such as an interposer 920) using an array of first solder material portions 940, and forming an underfill material portion 950 having the second Young's modulus that is lower than the first Young's modulus may be formed around the array of first solder material portions 940.

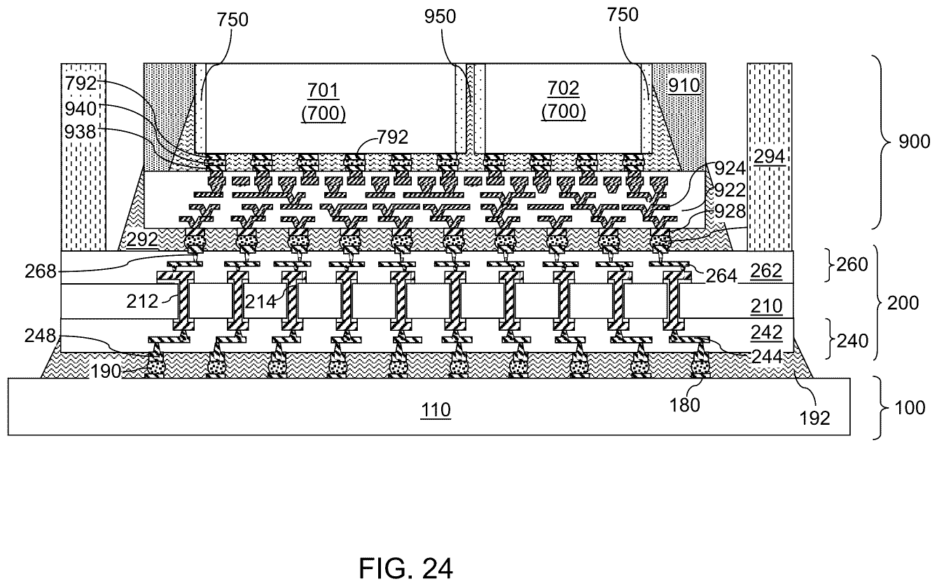

Referring to FIG. 24, the processing steps described with reference to FIGS. 11-18 may be performed to form a bonded assembly. For example, a fan-out package 900 may be attached to a packaging substrate 200, and the packaging substrate 200 may be attached to a printed circuit board 100.

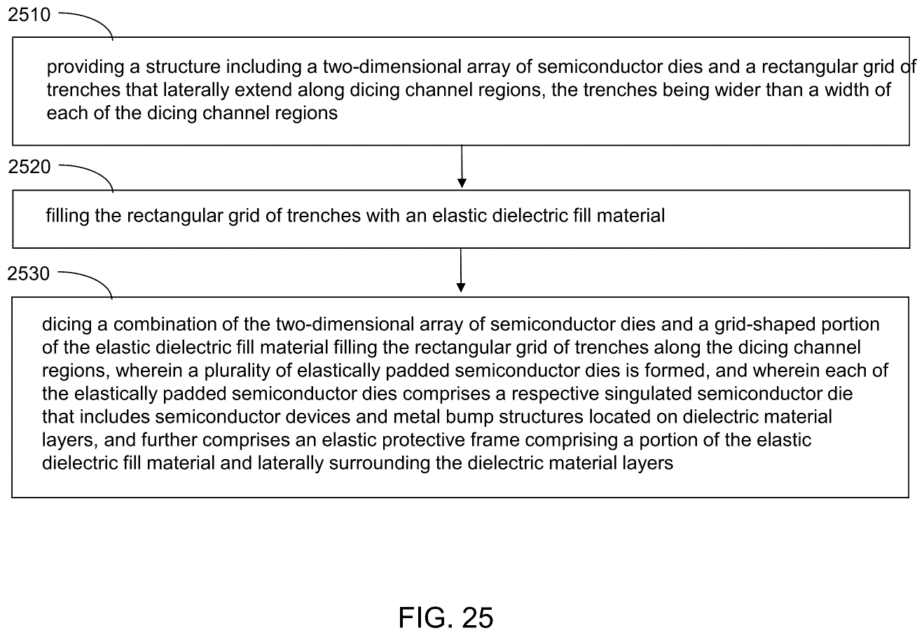

FIG. 25 is a first flowchart illustrating steps for forming a device structure according to an embodiment of the present disclosure.

Referring to step 2510 and FIGS. 1A-2B and 19A and 19B, a structure including a two-dimensional array of semiconductor dies 700 and a rectangular grid of trenches 779 that laterally extend along dicing channel regions DCR may be provided. The trenches 779 are wider than a width of each of the dicing channel regions DCR.

Referring to step 2520 and FIGS. 3A-4C and 20A-21B, the rectangular grid of trenches 779 may be filled with an elastic dielectric fill material.

Referring to step 2530 and FIGS. 5A-18 and 22A-24, a combination of the two-dimensional array of semiconductor dies 700 and a grid-shaped portion of the elastic dielectric fill material filling the rectangular grid of trenches 779 may be diced along the dicing channel regions DCR. A plurality of elastically padded semiconductor dies (700, 750) is formed. Each of the elastically padded semiconductor dies (700, 750) comprises a respective singulated semiconductor die (700, 750) that includes semiconductor devices 720 and metal bump structures 792 located on dielectric material layers 760, and further comprises an elastic protective material portion 750 comprising a portion of the elastic dielectric fill material and laterally surrounding the dielectric material layers 760.

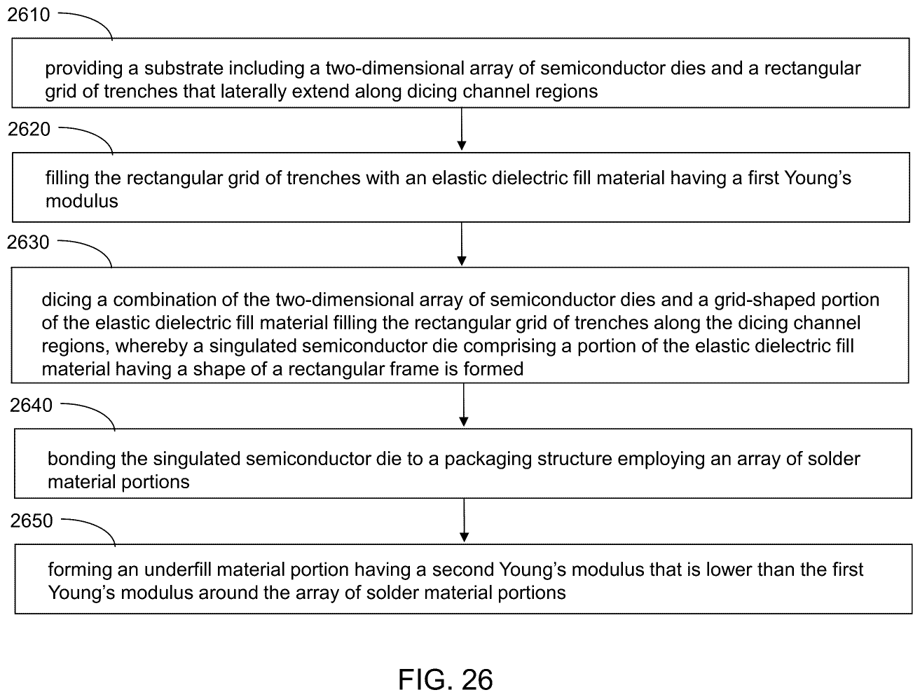

FIG. 26 is a second flowchart illustrating steps for forming a device structure according to an embodiment of the present disclosure.

Referring to step 2610 and FIGS. 1A-2B and 19A and 19B, a structure including a two-dimensional array of semiconductor dies 700 and a rectangular grid of trenches 779 that laterally extend along dicing channel regions DCR may be provided.

Referring to step 2620 and FIGS. 3A-4C and 20A-21B, the rectangular grid of trenches 779 may be filled with an elastic dielectric fill material having a first Young's modulus.

Referring to step 2630 and FIGS. 5A-5C and 22A-22C, a combination of the two-dimensional array of semiconductor dies 700 and a grid-shaped portion of the elastic dielectric fill material filling the rectangular grid of trenches 779 may be diced along the dicing channel regions DCR. A singulated semiconductor die (700, 750) comprising a portion of the elastic dielectric fill material having a shape of a rectangular frame is formed.

Referring to step 2640 and FIGS. 6-8B and 23, the singulated semiconductor die (700, 750) may be bonded to a packaging structure (such as an interposer 920) using an array of first solder material portions 940.

Referring to step 2650 and FIGS. 9A-18, 23, and 24, an underfill material portion 950 having a second Young's modulus that is lower than the first Young's modulus may be formed around the array of first solder material portions 940.

Referring to all drawings and according to various embodiments of the present disclosure, a device structure comprising an elastically padded semiconductor die is provided. The elastically padded semiconductor die (700, 750) comprises: a semiconductor die substrate 710; semiconductor devices 720 located on the semiconductor die substrate 710; metal interconnect structures 780 formed within dielectric material layers 760 and electrically connected to the metal interconnect structures 780; metal bump structures 792 located on a topmost dielectric material layer among the dielectric material layers 760; and an elastic protective material portion 750 comprising an elastic dielectric fill material and laterally surrounding the dielectric material layers 760 and at least an upper portion of the semiconductor die substrate 710.

In one embodiment, the device structure further comprises: a packaging structure (such as an interposer 920) comprising additional metal bump structures (such as interposer-side bonding structures 938); first solder material portions 940 that are bonded to the metal bump structures 792 and the additional metal bump structures (such as the interposer-side bonding structures 938); and an underfill material portion 950 laterally surrounding the first solder material portions 940. In one embodiment, the elastic protective material portion 750 has a first Young's modulus; and the underfill material portion 950 has a second Young's modulus that is less than the first Young's modulus.

In one embodiment, the semiconductor die substrate 710 comprises: a set of first sidewalls 711 in contact with inner sidewalls 751 of the elastic protective material portion 750; a set of second sidewalls 712 adjoined to, and are vertically coincident with, outer sidewalls 752 of the elastic protective material portion 750; and a frame-shaped ledge surface 713 having an inner periphery that coincides with a periphery of the set of first sidewalls 711 and having an outer periphery that coincides with a boundary between the set of second sidewalls 712 and the outer sidewalls 752 of the elastic protective material portion 750.

In one embodiment, the underfill material portion 950 contacts an entirety of outer sidewalls 752 of the elastic protective material portion 750 and contacts segments of sidewalls of the semiconductor die substrate 710. In one embodiment, an entirety of outer sidewalls 752 of the dielectric material layers 760 that are in contact with the elastic protective material portion 750 is located within vertical planes containing a set of sidewalls of the semiconductor die substrate 710. In one embodiment, the entirety of sidewalls of the semiconductor die substrate 710 is in contact with the elastic protective material portion 750.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a device structure, comprising:
providing a structure including a two-dimensional array of semiconductor dies and a rectangular grid of trenches that laterally extend along dicing channel regions, the trenches being wider than a width of each of the dicing channel regions;
filling the rectangular grid of trenches with an elastic dielectric fill material; and
dicing a combination of the two-dimensional array of semiconductor dies and a grid-shaped portion of the elastic dielectric fill material filling the rectangular grid of trenches along the dicing channel regions, wherein a plurality of elastically padded semiconductor dies is formed, and wherein each of the elastically padded semiconductor dies comprises a respective singulated semiconductor die that includes semiconductor devices and metal bump structures located on dielectric material layers, and further comprises an elastic protective material portion comprising a portion of the elastic dielectric fill material and laterally surrounding the dielectric material layers.

2. The method of claim 1, wherein:
the structure comprises a semiconductor substrate;
the two-dimensional array of semiconductor dies comprises portions of the semiconductor substrate that is enclosed by areas of the dicing channel regions; and
each of the singulated semiconductor dies comprises a respective diced portion of the semiconductor substrate.

3. The method of claim 2, wherein each of the singulated semiconductor dies comprises a respective semiconductor die substrate having a same material composition and a same thickness as the semiconductor substrate.

4. The method of claim 2, wherein the rectangular grid of trenches has a uniform depth that is greater than a total thickness of the dielectric material layers within each of the elastically padded semiconductor dies, and is less than a sum of said total thickness and a thickness of the semiconductor substrate.

5. The method of claim 2, wherein:
a recessed surface of the semiconductor substrate is physically exposed at a bottom of each of the trenches;
the method comprises applying the elastic dielectric fill material in the trenches and removing portions of the elastic dielectric fill material located outside the trenches; and
remaining portion of the elastic dielectric fill material in the trenches comprise a grid network of elastic dielectric fill material rails.

6. The method of claim 2, wherein the rectangular grid of trenches is formed by removing a semiconductor material of the semiconductor substrate within a grid-shaped area between a top surface of the semiconductor substrate and a horizontal plane located between the top surface of the semiconductor substrate and a bottom surface of the semiconductor substrate.

7. The method of claim 1, wherein:
the structure comprises a carrier substrate;
the two-dimensional array of semiconductor dies is attached to a top surface of the carrier substrate through a die attachment film; and
the rectangular grid of trenches comprises lateral gaps between neighboring pairs of semiconductor dies within the two-dimensional array of semiconductor dies.

8. The method of claim 7, wherein the elastic dielectric fill material is deposited directly on the die attachment film and on a set of sidewalls of the two-dimensional array of semiconductor dies.

9. The method of claim 7, wherein:
the combination of the two-dimensional array of semiconductor dies and the grid-shaped portion of the elastic dielectric fill material filling the rectangular grid of trenches comprises a reconstituted wafer;
the method comprises detaching the carrier substrate from the reconstituted wafer; and
the reconstituted wafer is diced along the dicing channel regions after detaching the carrier substrate from the reconstituted wafer.

10. A method of manufacturing a device structure, comprising:
providing a substrate including a two-dimensional array of semiconductor dies and a rectangular grid of trenches that laterally extend along dicing channel regions;
filling the rectangular grid of trenches with an elastic dielectric fill material having a first Young's modulus;
dicing a combination of the two-dimensional array of semiconductor dies and a grid-shaped portion of the elastic dielectric fill material filling the rectangular grid of trenches along the dicing channel regions, whereby a singulated semiconductor die comprising a portion of the elastic dielectric fill material having a shape of a rectangular frame is formed;
bonding the singulated semiconductor die to a packaging structure using an array of solder material portions; and
forming an underfill material portion having a second Young's modulus that is lower than the first Young's modulus around the array of solder material portions.

11. The method of claim 10, wherein the elastic dielectric fill material is selected from silicon oxide, silicon carbide, boron carbide, molding compound materials, and a polymer material.

12. The method of claim 10, wherein:
the first Young's modulus is in a range from 10 GPa to 90 GPa; and
the second Young's modulus is in a range from 3 GPa to 10 GPa.

13. The method of claim 10, wherein:
the elastic dielectric fill material comprises a first underfill material; and
the underfill material portion comprises a second underfill material having a different material composition than the first underfill material.

14. A device structure comprising an elastically padded semiconductor die, wherein the elastically padded semiconductor die comprises:
a semiconductor die substrate;
semiconductor devices located on the semiconductor die substrate;
metal interconnect structures formed within dielectric material layers and electrically connected to the metal interconnect structures;
metal bump structures located on a topmost dielectric material layer among the dielectric material layers; and
an elastic protective material portion comprising an elastic dielectric fill material and laterally surrounding the dielectric material layers and at least an upper portion of the semiconductor die substrate.

15. The device structure of claim 14, further comprising:
a packaging structure comprising additional metal bump structures;
solder material portions that are bonded to the metal bump structures and the additional metal bump structures; and
an underfill material portion laterally surrounding the solder material portions.

16. The device structure of claim 15, wherein:
the elastic protective material portion has a first Young's modulus; and
the underfill material portion has a second Young's modulus that is less than the first Young's modulus.

17. The device structure of claim 14, wherein the semiconductor die substrate comprises:
a set of first sidewalls in contact with inner sidewalls of the elastic protective material portion;
a set of second sidewalls adjoined to, and are vertically coincident with, outer sidewalls of the elastic protective material portion; and
a frame-shaped ledge surface having an inner periphery that coincides with a periphery of the set of first sidewalls and having an outer periphery that coincides with a boundary between the set of second sidewalls and the outer sidewalls of the elastic protective material portion.

18. The device structure of claim 14, wherein the underfill material portion contacts an entirety of outer sidewalls of the elastic protective material portion and contacts segments of sidewalls of the semiconductor die substrate.

19. The device structure of claim 14, wherein an entirety of outer sidewalls of the dielectric material layers that are in contact with the elastic protective material portion is located within vertical planes containing a set of sidewalls of the semiconductor die substrate.

20. The device structure of claim 14, wherein an entirety of sidewalls of the semiconductor die substrate is in contact with the elastic protective material portion.
